(19) United States
(12) Patent Application Publication
(10) Pub. No.: US 2006/0209915 A1
(43) Pub. Date: Sep. 21, 2006

(54) Photovoltaic device

(76) Inventor: Masaki Shima, Uji-shi (JP)

Correspondence Address: NDQ&M WATCHSTONE LLP, 1300 EYE STREET, NW, 400 EAST TOWER, WASHINGTON, DC, 20005, US

(21) Appl. No.: 11/350,899

(22) Filed: Feb. 10, 2006

(30) Foreign Application Priority Data
Feb. 10, 2005 (JP) JP 2005-034379

(51) Int. Cl. H01S 5/00

(52) U.S. Cl. 372/46.01

(57) ABSTRACT

An aspect of the present invention provides a photovoltaic device having a first semiconductor layer of a first conduction type and a third semiconductor layer of a second conductivity type. At least one of the first and third semiconductor layers includes an amorphous semiconductor layer. The amorphous semiconductor layer has a larger band gap than a non-monocrystal semiconductor layer having crystallinity. Accordingly, it is possible to increase a built-in electric field that is a potential difference between the Fermi level of the first semiconductor layer of the first conductivity type and the Fermi level of the third semiconductor layer of the second conductivity type.

### CROSS REFERENCE TO RELATED APPLICATIONS

This application is based upon and claims the benefit of priority from the prior Japanese Patent Application No. P2005-034379 filed on Feb. 10, 2005, the entire contents of which are incorporated herein by reference.

### BACKGROUND OF THE INVENTION

1. Field of the Invention

The present invention relates to a photovoltaic device, and particularly, to a photovoltaic device having at least one power generation unit including a plurality of semiconductor layers.

2. Description of Related Art

A photovoltaic device having an n-type layer, a photoelectric conversion layer, and a p-type layer each made of a microcrystal-silicon-based semiconductor layer is disclosed in Japanese Laid-open Patent Publication No. 2002-33500 (Patent Document 1). The microcrystal-silicon-based semiconductor contains Si as a composing element and includes many crystal grains whose maximum diameter is several hundreds of nanometers or smaller. It may contain an amorphous phase. The photovoltaic device of the Patent Document 1 employing the microcrystal-silicon-based semiconductor for a photoelectric conversion layer shows less photodegradation that may deteriorate conversion efficiency and absorbs a wide range of light, compared with a photovoltaic device employing an amorphous-silicon-based semiconductor for a photoelectric conversion layer. The photovoltaic device with an n-type layer, a photoelectric conversion layer, and a p-type layer each made of a microcrystal-silicon-based semiconductor layer as disclosed in the Patent Document 1 employs a substrate whose surface has irregularities. Sequentially formed on the substrate are a rear electrode, the n-type layer, the photoelectric conversion layer, the p-type layer, and a surface electrode. The surfaces of the rear electrode and n-type layer show irregularities due to the irregularities at the surface of the substrate. The surface irregularities of the rear electrode and n-type layer can scatter incident light, to thereby improve a light trapping effect.

The light trapping effect of the photovoltaic device disclosed in the Patent Document 1, however, is insufficient. More precisely, the absorption coefficient of the microcrystal-silicon-based semiconductor is one order of magnitude lower than that of an amorphous-silicon-based semiconductor. To realize the same light absorption as the photovoltaic device employing an amorphous-silicon-based semiconductor layer as a photoelectric conversion layer, the photovoltaic device employing a microcrystal-silicon-based semiconductor layer as a photoelectric conversion layer must thicken the photoelectric conversion layer. Even with the substrate having surface irregularities, thickening the photoelectric conversion layer results in smoothing the surface irregularities of the photoelectric conversion layer. Accordingly, the p-type layer and surface electrode successively formed on the photoelectric conversion layer have nearly flat surfaces, and the surfaces of the p-type layer and surface electrode hardly scatter incident light. In this way, the photovoltaic device of the Patent Document 1 achieves an insufficient light trapping effect on the surface side, is difficult to efficiently absorb incident light in the photoelectric conversion layer, and hardly increases a short-circuit current. According to the Patent Document 1 that forms the n-type layer and p-type layer each from a microcrystal-silicon-based semiconductor layer, a built-in electric field formed at a pin junction of the n-type layer, photoelectric conversion layer, and p-type layer may not be sufficiently expanded because the microcrystal-silicon-based semiconductor layers involve a small band gap. Due to this, it is difficult to increase an open-circuit voltage.

### SUMMARY OF THE INVENTION

A first aspect of the present invention provides a photovoltaic device having a first semiconductor layer of a first conduction type and a third semiconductor layer of a second conductivity type. At least one of the first and third semiconductor layers includes an amorphous semiconductor layer. The amorphous semiconductor layer has a larger band gap than a non-monocrystal semiconductor layer having crystallinity. Accordingly, it is possible to increase a built-in electric field that is a potential difference between the Fermi level of the first semiconductor layer of the first conductivity type and the Fermi level of the third semiconductor layer of the second conductivity type. This results in increasing the open-circuit voltage of the photovoltaic device.

Forming at least one of the first and third semiconductor layers from an amorphous semiconductor layer having a large band gap results in absorbing no light whose energy is smaller than the band gap. Namely, the amorphous semiconductor layer having a large band gap absorbs little light. This reduces a light absorption loss of at least one of the first and third semiconductor layers and makes a second semiconductor layer (photoelectric conversion layer) efficiently absorb incident light, thereby increasing the short-circuit current of the photovoltaic device. The layers except the amorphous semiconductor layer among the first, second, and third semiconductor layers may include non-monocrystal semiconductor layers having crystallinity. In addition, at least one of the non-monocrystal semiconductor layers having crystallinity may have a preferred orientation plane that is different from that of the other layer, so that at least one of the non-monocrystal semiconductor layers having crystallinity may have a preferred orientation plane that is apt to form an irregular surface. Even if the surface of the other layer is flat, the irregular surface of the at least one non-monocrystal semiconductor layer having crystallinity can scatter incident light. Namely, the power generation unit having these first, second, and third semiconductor layers can achieve a good light trapping effect, and the second semiconductor layer (photoelectric conversion layer) can efficiently absorb incident light, thereby increasing the short-circuit current of the photovoltaic device. In this way, the first aspect of the present invention can realize a large open-circuit voltage and a large short-circuit current, to improve the output performance of the photovoltaic device.

The first semiconductor layer includes at least an amorphous semiconductor layer and is arranged on a substrate opposite to a light incident side. The amorphous semiconductor layer of the first semiconductor layer may be arranged on the substrate side. This configuration sequentially forms, on the substrate, the first semiconductor layer, second semiconductor layer, and third semiconductor layer. Only the structure of the first to third semiconductor layers on the substrate is divided into a plurality of power generation units. Namely, the power generation units are each made of the first to third semiconductor layers on the substrate and are adjacent to each other. When the structure made of the first to third semiconductor layers is cut into the units from the third semiconductor layer toward the first semiconductor layer, the first semiconductor layer including the amorphous semiconductor layer may be incompletely cut. Even so, no leakage current is passed between the adjacent power generation units through the first semiconductor layer including the amorphous semiconductor layer because the amorphous semiconductor layer has a lower conductivity than the non-monocrystal semiconductor layer having crystallinity.

The third semiconductor layer may include at least one amorphous semiconductorlayerandmaybearrangedonthelightincidentside. This configuration can reduce a light absorption loss in the third semiconductor layer arranged on the light incident side, to make the second semiconductor layer (photoelectric conversion layer) more efficiently absorb incident light.

At least one of the first and third semiconductor layers may include a plurality of layers. In this case, at least one of the plurality of layers that form the at least one of the first and third semiconductor layers may be an amorphous semiconductor layer, and the others each may be a non-monocrystal semiconductor layer having crystallinity. The amorphous semiconductor layer among the layers forming the at least one of the first and third semiconductor layers has a large band gap to increase a built-in electric field at a pin junction.

In this case, the third semiconductor layer may include an amorphous semiconductor layer and a non-monocrystal semiconductor layer having crystallinity. In the third semiconductor layer, the amorphous semiconductor layer is first formed and on which the non-monocrystal semiconductor layer having crystallinity is formed. On the non-monocrystal semiconductor layer having crystallinity of the third semiconductor layer, an electrode layer is formed. In this configuration, the non-monocrystal semiconductor layer having crystallinity has a higher conductivity than the amorphous semiconductor layer, and therefore, the third semiconductor layer even with the amorphous semiconductor layer can suppress a contact resistance between the third semiconductor layer (the non-monocrystal semiconductor layer having crystallinity) and the electrode layer. This prevents a decrease in the fill factor of the photovoltaic device.

The non-monocrystal semiconductor layer having crystallinity among the layers that form the first, second, and third semiconductor layers may include a non-monocrystal silicon layer having crystallinity. At least one non-monocrystal silicon layer having crystallinity among the layers that form the first and third semiconductor layers may have a preferred orientation plane of (111). In this configuration, the non-monocrystal silicon layer having the preferred orientation plane of (111) is apt to have an irregular surface. Namely, at least one non-monocrystal silicon layer having crystallinity among the layers that form the first and third semiconductor layers may easily have irregularities at the surface thereof.

In this case, at least the non-monocrystal silicon layer that forms the second semiconductor layer may have a preferred orientation plane of (220). With this configuration, the second semiconductor layer (photoelectric conversion layer) having the preferred orientation plane of (220) has particularly good characteristics to improve the output performance of the photovoltaic device.

Here, a first conductivity type and a second conductivity type are opposite to each other. In other words, if the first conductivity type is an n-type, the second conductivity type is a p-type, and if the first conductivity type is a p-type, the second conductivity type is an n-type.

### BRIEF DESCRIPTION OF THE DRAWINGS

FIG. 1 is a sectional view showing the structure of a photovoltaic device according to an embodiment 1 of the present invention.

FIG. 2 is a graph showing X-ray diffraction peak strengths measured on the n-type layer 3, photoelectric conversion layer 4, and p-type layer 5 formed under the conditions shown in Table 1.

FIG. 3 is a sectional view showing the structure of the photovoltaic device according to the comparative example 1.

FIG. 4 is a graph showing X-ray diffraction peak strengths measured on the n-type layer 13, photoelectric conversion layer 14, and p-type layer 15 formed under the conditions shown in Table 2.

FIG. 5 is a sectional view showing the structure of a photovoltaic device according to a comparative example 2.

FIG. 6 is a graph showing X-ray diffraction peak strengths measured on the n-type layer 23, photoelectric conversion layer 24, and p-type layer 25 formed under the conditions shown in Table 3.

FIG. 7 is a sectional view showing the structure of a photovoltaic device according to a comparative example 3.

FIG. 8 is a graph showing X-ray diffraction peak strengths measured on the n-type layer 33, photoelectric conversion layer 34, and p-type layer 35 formed under the conditions shown in Table 4.

FIG. 9 is a sectional view showing the structure of a photovoltaic device according to an embodiment 2 of the present invention.

FIG. 10 is a graph showing X-ray diffraction peak strengths measured on the n-type layer 43, photoelectric conversion layer 44, and p-type layer 45 of the photovoltaic device of the embodiment 2 shown in FIG. 9 formed under the conditions of Table 6.

FIG. 11 is a sectional view showing the structure of the photovoltaic device according to the comparative example 4.

FIG. 12 is a graph showing X-ray diffraction peak strengths measured on the n-type layer 53, photoelectric conversion layer 54, and p-type layer 55 of the photovoltaic device of the comparative example 4 shown in FIG. 11 formed under the conditions shown in Table 7.

FIG. 13 is a sectional view showing the structure of a photovoltaic device according to the comparative example 5.

FIG. 14 is a graph showing X-ray diffraction peak strengths measured on the n-type layer 63, photoelectric conversion layer 64, and p-type layer 65 of the photovoltaic device of the comparative example 5 shown in FIG. 13 formed under the conditions shown in Table 8.

FIG. 15 is a sectional view showing the structure of a photovoltaic device according to an embodiment 3 of the present invention.

FIG. 16 is a graph showing X-ray diffraction peak strengths measured on the n-type layer 73, photoelectric conversion layer 74, first p-type layer 75a, and second p-type layer 75b of the photovoltaic device of the embodiment 3 shown in FIG. 15 formed under the conditions shown in Table 10.

FIG. 17 is a sectional view showing the structure of the photovoltaic device according to the comparative example 6.

FIG. 18 is a graph showing the X-ray diffraction peak strengths of an n-type layer, a photoelectric conversion layer, and a p-type layer of the photovoltaic device of the comparative example 6 shown in FIG. 17.

FIG. 19 shows an example of the layered photovoltaic device.

### DETAILED DESCRIPTION OF EMBODIMENTS

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

Prepositions, such as “on”, “over” and “above” are defined with respect to a surface, for example a layer surface, regardless of that surface's orientation in space. Preposition “above” may be used in the specification and claims even if a layer is in contact with another layer. Proposition “on” may be used in the specification and claims if a layer is not in contact with another layer, for example, there is an intervening layer between them.

### Embodiment 1

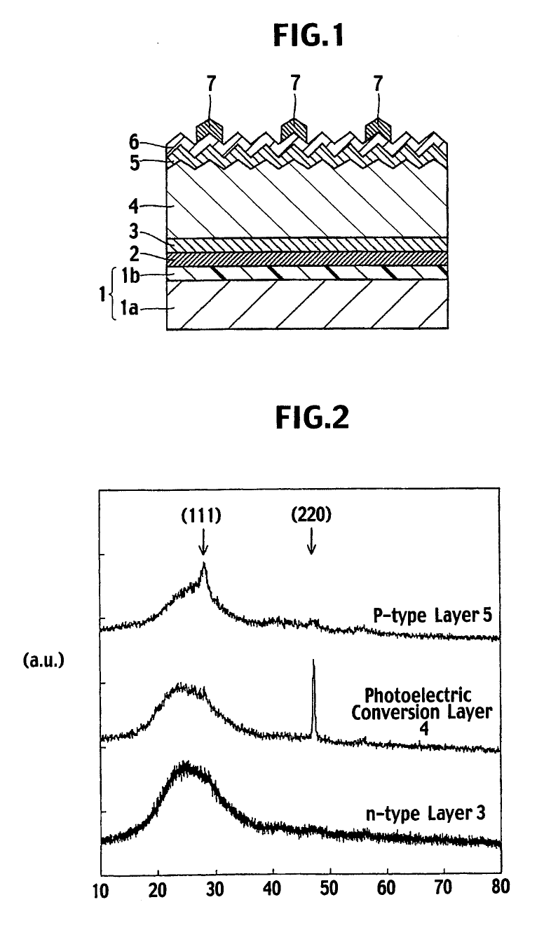

FIG. 1 is a sectional view showing the structure of a photovoltaic device according to an embodiment 1 of the present invention. The structure of the photovoltaic device according to the embodiment 1 will be explained with reference to FIG. 1.

The photovoltaic device according to the embodiment 1 has a stainless plate (SUS430) 1a that is 0.15 mm thick and is flat. Formed on the stainless plate 1a is a polyimide resin layer 1b of 20 μm thick. The stainless plate 1a and polyimide resin layer 1b form a substrate 1 having a flat surface. Formed on the substrate 1 (polyimide resin layer 1b) is a rear electrode 2 that is 200 nmthick, is made of Ag (silver), and is flat.

Sequentially formed on the rear electrode 2 are an n-type layer 3, a photoelectric conversion layer 4, and a p-type layer 5 having thicknesses of 20 nm, 2 μm, and 20 nm, respectively. The n-type layer 3, photoelectric conversion layer 4, and p-type layer 5 form a power generation unit.

According to the embodiment 1, the n-type layer 3 is an n-type amorphous silicon layer, the photoelectric conversion layer 4 is a non-doped microcrystal silicon layer, and the p-type layer 5 is a p-type microcrystal silicon layer. The photoelectric conversion layer has a preferred orientation plane of (220) and the p-type layer 5 has a preferred orientation plane of (111). The surface of the photoelectric conversion layer 4 is substantially flat and has gentle irregularities. The surface of the p-type layer 5 has pyramid-like (quadrangular-pyramid-like) irregularities. The n-type layer 3 is an example of the “first semiconductor layer” or “amorphous semiconductor layer” of the present invention. The photoelectric conversion layer 4 is an example of the “second semiconductor layer,” “non-monocrystal semiconductor layer,” or “non-monocrystal silicon layer” of the present invention. The p-type layer 5 is an example of the “third semiconductor layer,” 1“non-monocrystal semiconductor layer,” or “non-monocrystal silicon layer” of the present invention. Formed on the p-type layer 5 is a surface transparent electrode 6 that has a thickness of 80 nm and is made of ITO (indium tin oxide). Formed in a predetermined region on the surface transparent electrode 6 is a collector electrode 7 that has a thickness of 2 μm and is made of Ag. According to the photovoltaic device of the embodiment 1, light is made incident to a side (p-side) where the collector electrodes 7 are formed.

Manufacturing of the photovoltaic device

Processes of manufacturing the photovoltaic device according to the embodiment 1 will be explained. In FIG. 1, a flat stainless plate 1a of 0.15 mm thick is prepared. On the stainless plate 1a, a polyimide resin layer 1b is vapor-deposited and polymerized to a thickness of 20 μm. The stainless plate 1a and polyimide resin layer 1b constitute a substrate 1. An RF magnetron sputtering method is employed to form, on the substrate 1 (polyimide resin layer 1b), a flat rear electrode 2 of 200 nm thick from Ag. A plasma CVD (chemical vapor deposition) method is employed to sequentially form, on the rear electrode 2, semiconductor layers that form a power generation unit. According to the embodiment 1, the sequentially formed are an n-type amorphous Si layer serving as the n-type layer 3, a non-doped microcrystal Si layer serving as the photoelectric conversion layer 4, and a p-type microcrystal Si layer serving as the p-type layer 5. At this time, the embodiment 1 forms the photoelectric conversion layer 4 to have a preferred orientation plane of (220) and the p-type layer 5 to have a preferred orientation plane of (111). The n-type layer 3, photoelectric conversion layer 4, and p-type layer 5 have thicknesses of 20 nm, 2 μm, and 20 nm, respectively. Conditions to form the n-type layer 3, photoelectric conversion layer 4, and p-type layer 5 are as mentioned in Table 1.

TABLE 1

| | Substrate | Reaction | | Gas flow |
|---|---|---|---|---|
| | temperature | pressure | Incident | rate |
| Embodiment 1 | (° C.) | (Pa) | power (W) | (sccm) |
| N-type layer | 160 | 26 | 20 | SiH₄: 20 |
| | | | | H₂: 80 |
| | | | | PH₃: 0.2 |
| Photoelectric | 200 | 133 | 30 | SiH₄: 20 |
| conversion | | | | H₂: 400 |
| layer | | | | |
| P-type layer | 160 | 133 | 240 | SiH₄: 10 |
| | | | | H₂: 2000 |
| | | | | B₂H₆: 0.2 |

As shown in Table 1, the n-type layer 3, i.e., the n-type amorphous Si layer is formed with a substrate temperature of 160° C., a reaction pressure of 26 Pa, and a high-frequency power of 20 W. When forming the n-type layer 3, gas flow rates are set as 20 sccm for SiH₄ gas, 80 sccm for H₂ gas, and 0.2 sccm for PH₃ gas. The photoelectric conversion layer 4, i.e., the non-doped microcrystal Si layer having a preferred orientation plane of (220) is formed with a substrate temperature of 200° C., a reaction pressure of 133 Pa, and a high-frequency power of 30 W. When forming the photoelectric conversion layer 4, gas flow rates are set as 20 sccm for SiH₄ gas and 400 sccm for H₂ gas. The p-type layer 5, i.e., the p-type microcrystal Si layer having a preferred orientation plane of (111) is formedwitha substrate temperature of 160° C., areaction pressure of 133 Pa, and a high-frequency power of 240 W. When forming the p-type layer 5, gas flow rates are set as 10 sccm for SiH₄ gas, 2000 sccm for H₂ gas, and 0.2 sccm for B₂H₆ gas.

FIG. 2 is a graph showing X-ray diffraction peak strengths measured on the n-type layer 3, photoelectric conversion layer 4, and p-type layer 5 formed under the conditions shown in Table 1. It is understood from FIG. 2 that the n-type layer 3 according to the embodiment 1 has no diffraction peak. The (220) diffraction peak strength of the photoelectric conversion layer 4 is higher than the (111) diffraction peak strength thereof. The (111) diffraction peak strength of the p-type layer 5 is higher than the (220) diffraction peak strength thereof. Namely, the graph of FIG. 2 confirms that, according to the embodiment 1, the n-type layer 3 is amorphous, the photoelectric conversion layer 4 has a preferred orientation plane of (220), and the p-type layer 5 has a preferred orientation plane of (111).

When a microcrystal Si layer is formed to have a preferred orientation plane of (111), it is known that the surface thereof is apt to have pyramid-like irregularities. On the other hand, when a microcrystal Si layer is formed to have a preferred orientation plane of (220), it is known that the surface thereof is apt to have a flat shape. These will be the reasons why the surface of the photoelectric conversion layer 4 of FIG. 1 according to the embodiment 1 is nearly flat and why the surface of the p-type layer 5 has pyramid-like irregularities.

Thereafter, an RF magnetron sputtering method is employed to form, on the p-type layer 5, a surface transparent electrode 6 of 80 nm thick from ITO. A vacuum vapor deposition method is employed to form, in a predetermined region on the surface transparent electrode 6, a collector electrode 7 of 2 μm thick from Ag. This completes the photovoltaic device of FIG. 1 according to the embodiment 1.

### COMPARATIVE EXAMPLE 1

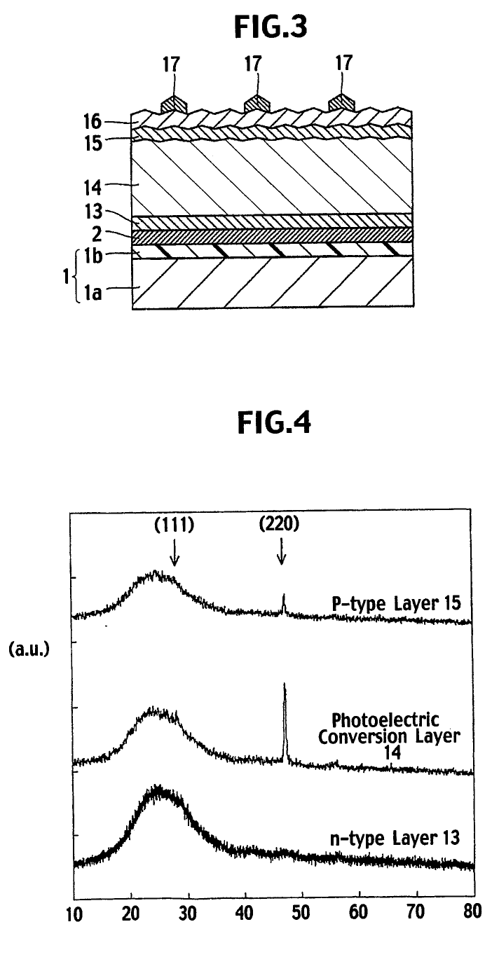

Photovoltaic devices according to comparative examples 1 to 3 will be explained in connection with the embodiment 1. FIG. 3 is a sectional view showing the structure of the photovoltaic device according to the comparative example 1. FIG. 4 is a graph showing the X-ray diffraction peak strengths of an n-type layer, a photoelectric conversion layer, and a p-type layer of the photovoltaic device of the comparative example 1 shown in FIG. 3. With reference to FIGS. 3 and 4, processes of manufacturing the photovoltaic device according to the comparative example 1 will be explained. Unlike the embodiment 1, the comparative example 1 employs an amorphous Si layer as the n-type layer andamicrocrystal Silayerhavingapreferredorientationplaneof (220) as each of the photoelectric conversion layer and p-type layer.

Manufacturing of the photovoltaic device

In FIG. 3, like the embodiment 1, a stainless plate 1a and a polyimide resin layer 1b are prepared to form a substrate 1. On the substrate 1, a rear electrode 2 is formed. A plasma CVD method is employed to sequentially form, on the rear electrode 2, semiconductor layers that form a power generation unit. According to the comparative example 1, the sequentially formed are an n-type amorphous Si layer serving as the n-type layer 13, a non-doped microcrystal Si layer serving as the photoelectric conversion layer 14, and a p-type microcrystal Si layer serving as the p-type layer 15. At this time, the comparative example 1 forms each of the photoelectric conversion layer 14 and p-type layer 15 to have a preferred orientation plane of (220). The n-type layer 13, photoelectric conversion layer 14, and p-type layer 15 have thicknesses of 20 nm, 2 μm, and 20 nm, respectively. Conditions to form the n-type layer 13, photoelectric conversion layer 14, and p-type layer 15 are as mentioned in Table 2.

TABLE 2

| | Substrate | Reaction | | Gas flow |
|---|---|---|---|---|
| Comparative | temperature | pressure | Incident | rate |
| example 1 | (° C.) | (Pa) | power (W) | (sccm) |
| N-type layer | 160 | 26 | 20 | SiH₄: 20 |
| | | | | H₂: 80 |
| | | | | PH₃: 0.2 |
| Photoelectric | 200 | 133 | 30 | SiH₄: 20 |
| conversion layer | | | | H₂: 400 |
| P-type layer | 160 | 133 | 60 | SiH₄: 2 |
| | | | | H₂: 150 |
| | | | | B₂H₆: 0.2 |

As shown in Table 2, the n-type layer 13, i.e., the n-type amorphous Si layer is formed with a substrate temperature of 160° C., a reaction pressure of 26 Pa, and a high-frequency power of 20 W. When forming the n-type layer 13, gas flow rates are set as 20 scam for SiH₄ gas, 80 scam for H₂ gas, and 0.2 scam for PH₃ gas. The conditions to form the n-type layer 13 are the same as those for the n-type layer 3 of the embodiment 1.

The photoelectric conversion layer 14, i.e., the non-doped microcrystal Si layer having a preferred orientation plane of (220) is formed with a substrate temperature of 200° C., a reaction pressure of 133 Pa, and a high-frequency power of 30 W. When forming the photoelectric conversion layer 14, gas flow rates are set as 20 scam for SiH₄ gas and 400 scam for H₂ gas. The conditions to form the photoelectric conversion layer 14 are the same as those for the photoelectric conversion layer 4 of the embodiment 1.

The p-type layer 15, i.e., the p-type microcrystal Si layer having a preferred orientation plane of (220) is formed with a substrate temperature of 160° C., a reaction pressure of 133 Pa, and a high-frequency power of 60 W. When forming the p-type layer 15, gas flow rates are set as 2 scam for SiH₄ gas, 150 scam for H₂ gas, and 0.2 scam for B₂H₆ gas.

FIG. 4 is a graph showing X-ray diffraction peak strengths measured on the n-type layer 13, photoelectric conversion layer 14, and p-type layer 15 formed under the conditions shown in Table 2. It is understood from FIG. 4 that the n-type layer 13 according to the comparative example 1 has no diffraction peak. The photoelectric conversion layer 14 and p-type layer 15 have nearly the same X-ray diffraction spectrum. It is understoodthat the (220) diffraction peak strength of each of the photoelectric conversion layer 14 and p-type layer 15 is higher than the (111) diffraction peak strength thereof. Namely, the graph of FIG. 4 confirms that, according to the comparative example 1, the n-type layer 13 is amorphous and each of the photoelectric conversion layer 14 and p-type layer 15 has a preferred orientation plane of (220). These will be the reasons why the surfaces of the photoelectric conversion layer 14 and p-type layer 15 are nearly flat as shown in FIG. 3.

Thereafter, like the embodiment 1, an RF magnetron sputtering method is employed to form, on the p-type layer 15, a surface transparent electrode 16 of 80 nm thick from ITO. A vacuum vapor deposition method is employed to form, in a predetermined region on the surface transparent electrode 16, a collector electrode 17 of 2 μm thick from Ag. This completes the photovoltaic device of FIG. 3 according to the comparative example 1. According to the photovoltaic device of the comparative example 1, light is made incident to a side (p-side) where the collector electrodes 17 are formed.

### COMPARATIVE EXAMPLE 2

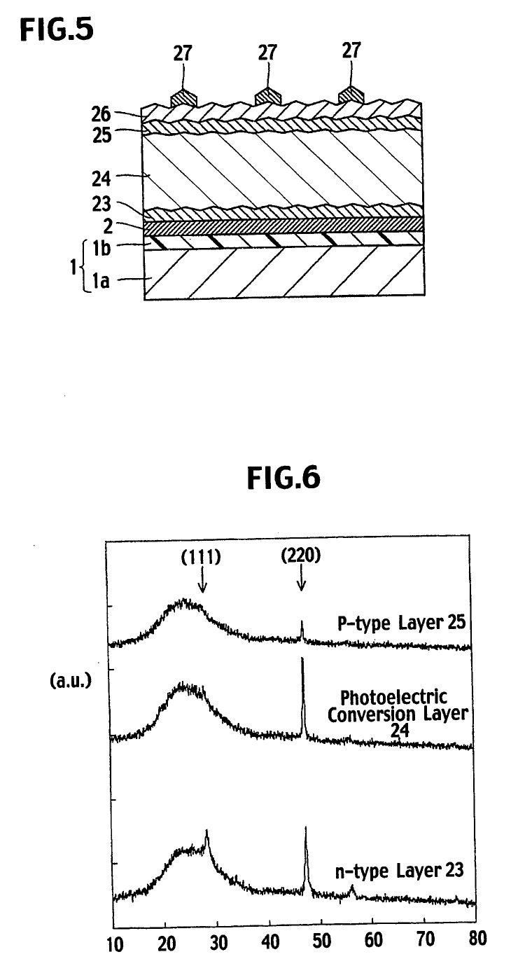

FIG. 5 is a sectional view showing the structure of a photovoltaic device according to a comparative example 2. FIG. 6 is a graph showing the X-ray diffraction peak strengths of an n-type layer, a photoelectric conversion layer, and a p-type layer of the photovoltaic device of the comparative example 2 shown in FIG. 5. With reference to FIGS. 5 and 6, processes of manufacturing the photovoltaic device according to the comparative example 2 will be explained. Unlike the embodiment 1, the comparative example 2 employs a microcrystal Si layer havingapreferredorientationplaneof (220) aseachof then-type layer, photoelectric conversion layer, and p-type layer.

Manufacturing of the photovoltaic device

In FIG. 5, like the embodiment 1, a stainless plate 1a and a polyimide resin layer 1b are prepared to form a substrate 1. On the substrate 1, a rear electrode 2 is formed. A plasma CVD method is employed to sequentially form, on the rear electrode 2, semiconductor layers that form a powergeneration unit. According to the comparative example 2, the sequentially formed are an n-type microcrystal Si layer serving as the n-type layer 23, a non-doped microcrystal Si layer serving as the photoelectric conversion layer 24, and a p-type microcrystal Si layer serving as the p-type layer 25. At this time, the comparative example 2 forms each of the n-type layer 23, photoelectric conversion layer 24 and p-type layer 25 to have a preferred orientation plane of (220). The n-type layer 23, photoelectric conversion layer 24, and p-type layer 25 have thicknesses of 20 nm, 2 μm, and 20 nm, respectively. Conditions to form the n-type layer 23, photoelectric conversion layer 24, and p-type layer 25 are as mentioned in Table 3.

TABLE 3

| | Substrate | Reaction | | Gas flow |
|---|---|---|---|---|
| Comparative | temperature | pressure | Incident | rate |
| example 2 | (° C.) | (Pa) | power (W) | (sccm) |
| N-type layer | 160 | 133 | 100 | SiH₄: 3 |
| | | | | H₂: 200 |
| | | | | PH₃: 0.6 |
| Photoelectric | 200 | 133 | 30 | SiH₄: 20 |
| conversion layer | | | | H₂: 400 |
| P-type layer | 160 | 133 | 60 | SiH₄: 2 |
| | | | | H₂: 150 |
| | | | | B₂H₆: 0.2 |

As shown in Table 3, the n-type layer 23, i.e., the n-type microcrystal Si layer is formed with a substrate temperature of 160° C., a reaction pressure of 133 Pa, and a high-frequency power of 100 W. When forming the n-type layer 23, gas flow rates are set as 3 sccm for SiH₄ gas, 200 scam for H₂ gas, and 0.6 scam for PH₃ gas. The photoelectric conversion layer 24, i.e., the non-doped microcrystal Si layer having a preferred orientation plane of (220) is formed with a substrate temperature of 200° C., a reaction pressure of 133 Pa, and a high-frequency power of 30 W. When forming the photoelectric conversion layer 24, gas flow rates are set as 20 scam for SiH₄ gas and 400 scam for H₂ gas. The conditions to form the photoelectric conversion layer 24 are the same as those for the photoelectric conversion layer 4 of the embodiment 1.

The p-type layer 25, i.e., the p-type microcrystal Si layer having a preferred orientation plane of (220) is formed with a substrate temperature of 160° C., a reaction pressure of 133 Pa, and a high-frequency power of 60 W. When forming the p-type layer 25, gas flow rates are set as 2 scam for SiH₄ gas, 150 scam for H₂ gas, and 0.2 scam for B₂H₆ gas. The conditions to form the p-type layer 25 are the same as those for the p-type layer 15 of the comparative example 1.

FIG. 6 is a graph showing X-ray diffraction peak strengths measured on the n-type layer 23, photoelectric conversion layer 24, and p-type layer 25 formedunderthe conditions shown in Table 3. According to the comparative example 2 shown in FIG. 6, the n-type layer 23, photoelectric conversion layer 24, and p-type layer 25 have nearly the same X-ray diffraction spectrum. It is understood that the (220) diffraction peak strength of each of the n-type layer 23, photoelectric conversion layer 24, and p-type layer 25 is higher than the (111) diffraction peak strength thereof. Namely, the graph of FIG. 6 confirms that, according to the comparative example 2, each of the n-type layer 23, photoelectric conversion layer 24, and p-type layer 25 has a preferred orientation plane of (220). This will be the reason why the surfaces of the n-type layer 23, photoelectric conversion layer 24, and p-type layer 25 are nearly flat as shown in FIG. 5.

Thereafter, like the embodiment 1, an RF magnetron sputtering method is employed to form, on the p-type layer 25, a surface transparent electrode 26 of 80 nm thick from ITO. A vacuum vapor deposition method is employed to form, in a predetermined region on the surface transparent electrode 26, a collector electrode 27 of 2 μm thick from Ag. This completes the photovoltaic device of FIG. 5 according to the comparative example 2. According to the photovoltaic device of the comparative example 2, light is made incident to a side (p-side) where the collector electrodes 27 are formed.

### COMPARATIVE EXAMPLE 3

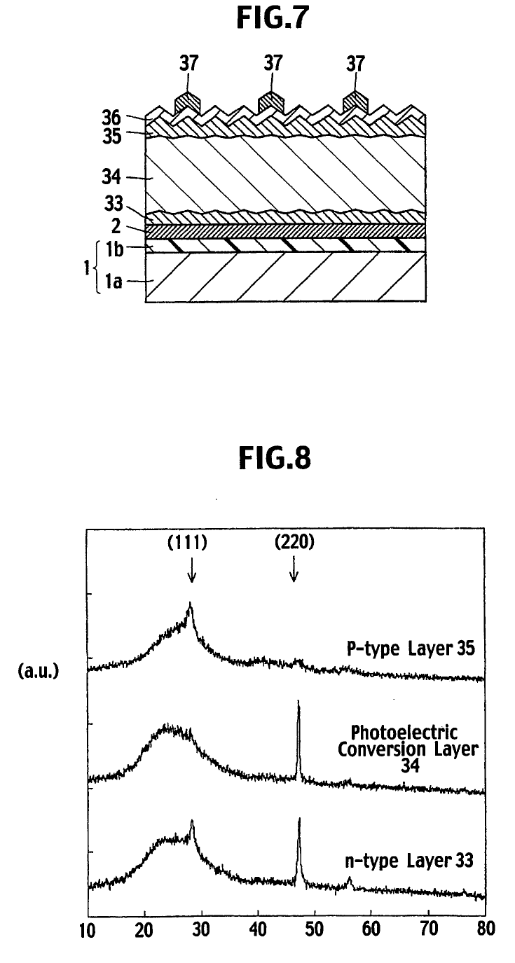

FIG. 7 is a sectional view showing the structure of a photovoltaic device according to a comparative example 3. FIG. 8 is a graph showing the X-ray diffraction peak strengths of an n-type layer, a photoelectric conversion layer, and a p-type layer of the photovoltaic device of the comparative example 3 shown in FIG. 7. With reference to FIGS. 7 and 8, processes of manufacturing the photovoltaic device according to the comparative example 3 will be explained. Unlike the embodiment 1, the comparative example 3 employs a microcrystal silicon layer having a preferred orientation plane of (220) as each of the n-type layer and photoelectric conversion layer, and a microcrystal Si layer having a preferred orientation plane of (111) as the p-type layer.

Manufacturing of the photovoltaic device

In FIG. 7, like the embodiment 1, a stainless plate 1a and a polyimide resin layer 1b are prepared to form a substrate 1. On the substrate 1, a rear electrode 2 is formed. A plasma CVD method is employed to sequentially form, on the rear electrode 2, semiconductor layers that form a power generation unit. According to the comparative example 3, the sequentially formed are an n-type microcrystal Si layer serving as the n-type layer 33, a non-doped microcrystal Si layer serving as the photoelectric conversion layer 34, and a p-type microcrystal Si layer serving as the p-type layer 35. At this time, the comparative example 3 forms each of the n-type layer 33 and photoelectric conversion layer 34 to have a preferred orientation plane of (220), and the p-type layer 35 to have a preferred orientation plane of (111). The n-type layer 33, photoelectric conversion layer 34, and p-type layer 35 have thicknesses of 20 nm, 2 μm, and 20 nm, respectively. Conditions to form the n-type layer 33, photoelectric conversion layer 34, and p-type layer 35 are as mentioned in Table 4.

TABLE 4

| | Substrate | Reaction | | Gas flow |
|---|---|---|---|---|
| Comparative | temperature | pressure | Incident | rate |
| example 3 | (° C.) | (Pa) | power (W) | (sccm) |
| N-type layer | 160 | 133 | 100 | SiH₄: 3 |
| | | | | H₂: 200 |
| | | | | PH₃: 0.6 |
| Photoelectric | 200 | 133 | 30 | SiH₄: 20 |
| conversion layer | | | | H₂: 400 |
| P-type layer | 160 | 133 | 240 | SiH₄: 10 |
| | | | | H₂: 2000 |
| | | | | B₂H₆: 0.2 |

As shown in Table 4, the n-type layer 33, i.e., the n-type microcrystal Si layer is formed with a substrate temperature of 160° C., a reaction pressure of 133 Pa, and a high-frequency power of 100 W. When forming the n-type layer 33, gas flow rates are set as 3 scam for SiH₄ gas, 200 scam for H₂ gas, and 0.6 scam for PH₃ gas. The conditions to form the n-type layer 33 are the same as those for the n-type layer 23 of the comparative example 2.

The photoelectric conversion layer 34, i.e., the non-doped microcrystal Si layer having a preferred orientation plane of (220) is formed with a substrate temperature of 200° C., a reaction pressure of 133 Pa, and a high-frequency power of 30 W. When forming the photoelectric conversion layer 34, gas flow rates are set as 20 scam for SiH₄ gas and 400 scam for H₂ gas. The conditions to form the photoelectric conversion layer 34 are the same as those for the photoelectric conversion layer 4 of the embodiment 1.

The p-type layer 35, i.e., the p-type microcrystal Si layer having a preferred orientation plane of (111) is formed with a substrate temperature of 160° C., a reaction pressure of 133 Pa, and a high-frequency power of 240 W. When forming the p-type layer 35, gas flow rates are set as 10 scam for SiH₄ gas, 2000 scam for H₂ gas, and 0.2 scam for B₂H₆ gas. The conditions to form the p-type layer 35 are the same as those for the p-type layer 5 of the embodiment 1.

FIG. 8 is a graph showing X-ray diffraction peak strengths measured on the n-type layer 33, photoelectric conversion layer 34, and p-type layer 35 formed under the conditions shown in Table 4.

According to the comparative example 3 shown in FIG. 8, the n-type layer 33 and photoelectric conversion layer 34 have nearly the same X-ray diffraction spectrum. It is understood that the (220) diffraction peak strength of each of the n-type layer 33 and photoelectric conversion layer 34 is higher than the (111) diffraction peak strength thereof. It is understood that the (111) diffraction peak strength of the p-type layer 35 is higher than the (220) diffraction peak strength thereof. Namely, the graph of FIG. 8 confirms that, according to the comparative example 3, each of the n-type layer 33 and photoelectric conversion layer 34 has a preferred orientation plane of (220) and the p-type layer 35 has a preferred orientation plane of (111). These will be the reasons why the surfaces of the n-type layer 33 and photoelectric conversion layer 34 are nearly flat and why the surface of the p-type layer 35 has pyramid-like irregularities, as shown in FIG. 7.

Thereafter, like the embodiment 1, an RF magnetron sputtering method is employed to form, on the p-type layer 35, a surface transparent electrode 36 of 80 nm thick from ITO. A vacuum vapor deposition method is employed to form, in a predetermined region on the surface transparent electrode 36, a collector electrode 37 of 2 μm thick from Ag. This completes the photovoltaic device of FIG. 7 according to the comparative example 3. According to the photovoltaic device of the comparative example 3, light is made incident to a side (p-side) where the collector electrodes 37 are formed.

Output performance test on embodiment 1 and comparative examples 1 to 3 To measure the output performance of the photovoltaic devices according to the embodiment 1 and comparative examples 1 to 3, a solar simulator is used at a light spectrum of AM 1.5, a light intensity of 100 mW/cm², and a measuring temperature of 25° C. Here, the AM (air mass) is the ratio of a path of direct solar radiation passing through the atmosphere to a perpendicular path passing through the standard atmosphere (at a standard pressure of 1013 hPa). Results of the measurement are shown in Table 5. The normalized conversion efficiency, normalized open-circuit voltage, and normalized short-circuit current shown in Table 5 are values normalized with the conversion efficiency, open-circuit voltage, and short-circuit current of the comparative example 2 serving as a reference value “1.”

TABLE 5

| | Normalized | Normalized | Normalized |
|---|---|---|---|
| | conversion | open-circuit | short-circuit |
| | efficiency | voltage | current |
| Embodiment 1 | 1.04 | 1.03 | 1.03 |
| Comparative example 1 | 1.02 | 1.03 | 1.01 |
| Comparative example 2 | 1.00 | 1.00 | 1.00 |
| Comparative example 3 | 1.01 | 0.99 | 1.01 |

Table 5 shows that, with the n-type layer being an n-type amorphous Si layer, the embodiment 1 with the p-type layer 5 having a preferred orientation plane of (111) has a higher short-circuit current than the comparative example 1 with the p-type layer 15 having a preferred orientation plane of (220). More precisely, the embodiment 1 and comparative example 1 demonstrate normalized short-circuit current values of 1.03 and 1.01, respectively. This is because the embodiment 1 arranges, on the surface side, the p-type layer 5 whose surface has pyramid-like irregularities to scatter incident light and realize a good light trapping effect. As a result, the photoelectric conversion layer 4 of the embodiment 1 can efficiently absorb the incident light. On the other hand, the comparative example 1 arranges, on the surface side, the p-type layer 15 whose surface is nearly flat, to hardly realize a good light trapping effect on the surface side. The embodiment 1 and comparative example 1 both realize a normalized open-circuit voltage of 1.03.

Comparison between the embodiment 1 and the comparative example 1 tells that the conversion efficiency (1.04) of the embodiment 1 is higher than the conversion efficiency (1.02) of the comparative example 1. This indicates that arranging, on the surface side, the p-type layer 5 whose surface has pyramid-like irregularities increases the conversion efficiency.

Table 5 also proves that the embodiment 1 employing an amorphous Si layer as the n-type layer 3 among the semiconductor layers that form a power generation unit has a higher open-circuit voltage than any one of the comparative examples 2 and 3 each employing microcrystal Si layers for all of the semiconductor layers that form a power generation unit. More precisely, the normalized open-circuit voltage of the embodiment 1 is 1.03, that of the comparative example 2 is 1.00, and that of the comparative example 3 is 0.99. The reason of this may be that the embodiment 1 forms the n-type layer 3 with an amorphous Si layer whose band gap is larger than a microcrystal Si layer, thereby increasing a built-in electric field at a pin junction of the n-type layer 3, photoelectric conversion layer 4, and p-type layer 5. On the other hand, each of the comparative examples 2 and 3 forms each of the semiconductor layers of a power generation unit with a microcrystal Si layer having a small band gap, to reduce a built-in electric field at a pin junction of the n-type layer 23 (33), photoelectric conversion layer 24 (34), and p-type layer 25 (35) smaller than that of the embodiment 1.

Table 5 also clarifies that the embodiment 1 employing an amorphous Si layer as the n-type layer 3 among the semiconductor layers of a power generation unit has a larger short-circuit current than any one of the comparative examples 2 and 3 each employing a microcrystal Si layer for every semiconductor layer of a power generation unit. More precisely, the normalized short-circuit current of the embodiment 1 is 1.03, that of the comparative example 2 is 1.00, and that of the comparative example 3 is 1.01. By forming the n-type layer 3 with an amorphous Si layer whose band gap is larger than that of a microcrystal Si layer, the embodiment 1 can reduce the light absorption loss of the n-type layer 3, thereby efficiently absorb incident light in the photoelectric conversion layer 4. On the other hand, by forming the n-type layer 23 (33) with a microcrystal Si layer of small band gap, the comparative examples 2 and 3 each cause a larger light absorption loss in the n-type layer 23 (33), thereby reducing incident light absorption by the photoelectric conversion layer 24 (34) smaller than the embodiment 1. In addition, the comparative example 2 arranges, on the surface side, the p-type layer 25 having a nearly flat surface, to hardly realize a good light trapping effect on the surface side, as is seen in the comparative example 1.

Comparison between the embodiment 1 and the comparative examples 2 and 3 tells that the conversion ef f iciency (1.04) of the embodiment 1 is higher than the conversion efficiency (1.00) of the comparative example 2 or the conversion efficiency (1.01) of the comparative example 3. This indicates that forming the n-type layer 3 with an amorphous Si layer increases the conversion efficiency.

As mentioned above, the embodiment 1 employs an amorphous Si layer as the n-type layer 3 among the semiconductor layers that form a power generation unit. The amorphous Si layer has a larger band gap than a microcrystal Si layer, and therefore, can increase a built-in electric field that is a potential difference between the Fermi level of the n-type layer 3 and the Fermi level of the p-type layer 5. This results in increasing the open-circuit voltage of the photovoltaic device. The amorphous Si layer that forms the n-type layer 3 does not absorb long-wavelength light that has lower energy than the bandgap of the amorphous Si layer. Namely, the amorphous Si layer having a large band gap hardly absorbs light, thereby reducing the light absorption loss of the n-type layer 3. This makes the photoelectric conversion layer 4 efficiently absorb incident light, to increase the short-circuit current of the photovoltaic device. The embodiment 1 employs a microcrystal Si layer having a preferred orientation plane of (111) to form the p-type layer 5 among the semiconductor layers that form a power generation unit. The microcrystal Si layer having a preferred orientation plane of (111) is apt to form an irregular surface. Even if the surfaces of the semiconductor layers except the p-type layer 5 are substantially flat, the p-type layer 5 will have an irregular surface to scatter incident light. Consequently, the power generation unit including the n-type layer 3, photoelectric conversion layer 4, and p-type layer 5 can realize a good light trapping effect, the photoelectric conversion layer 4 can efficiently absorb incident light, and the photovoltaic device can provide a large short-circuit current. In this way, the photovoltaic device according to the embodiment 1 can realize a large open-circuit voltage and a large short-circuit current to improve output performance.

The embodiment 1 arranges an amorphous Si layer serving as the n-type layer 3 on the substrate 1. Namely, the embodiment 1 sequentially forms the n-type layer 3, photoelectric conversion layer 4, and p-type layer 5 on the single substrate 1. The embodiment 1 divides only a structural part including the n-type layer 3, photoelectric conversion layer 4, and p-type layer 5 on the substrate 1 into a plurality of units. Namely, on the single substrate 1, the embodiment 1 forms a plurality of power generation units that are adjacent to each other and each include the n-type layer 3, photoelectric conversion layer 4, and p-type layer 5. For this, the structural part including the n-type layer 3, photoelectric conversion layer 4, and p-type layer 5 is cut into units from the p-type layer 5 toward the n-type layer 3. Even if the n-type layer 3, i.e., the amorphous Si layer is incompletely cut, no leak current will be passed between the adjacent power generation units through the n-type layer 3 because the amorphous Si layer that forms the n-type layer 3 has a lower conductivity than a microcrystal Si layer.

The photoelectric conversion layer 4 of the photovoltaic device according to the embodiment 1 has apreferredorientation plane of (220) to provide the photoelectric conversion layer 4 with proper characteristics and improve the output performance of the photovoltaic device.

### Embodiment 2

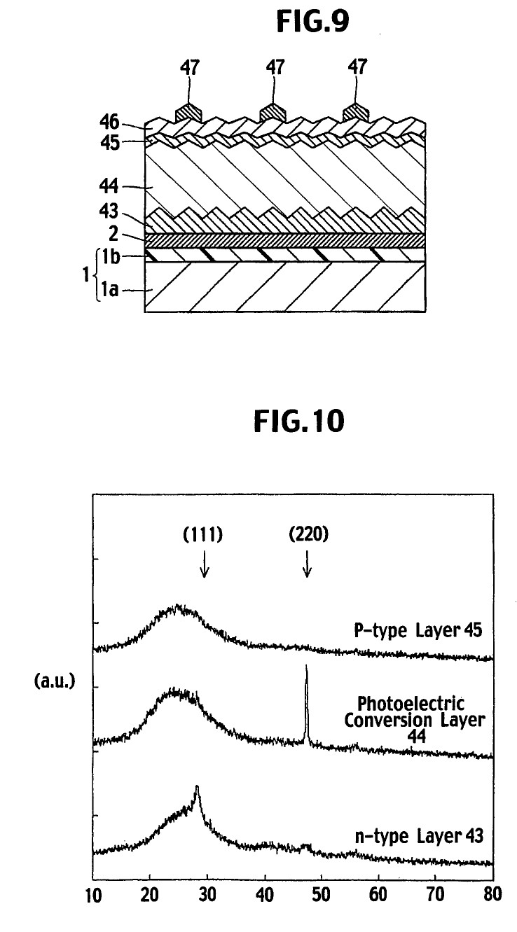

FIG. 9 is a sectional view showing the structure of a photovoltaic device according to an embodiment 2 of the present invention. Unlike the embodiment 1, the embodiment 2 employs an n-type layer having a preferred orientation plane of (111), a photoelectric conversion layer having a preferred orientation plane of (220), and an amorphous p-type layer. The structure of the photovoltaic device according to the embodiment 2 will be explained with reference to FIG. 9.

Like the embodiment 1, the photovoltaic device of the embodiment 2 shown in FIG. 9 employs a stainless plate 1a and a polyimide resin layer 1b to form a substrate 1. On the substrate 1, a rear electrode 2 is formed. On the rear electrode 2, the n-type layer 43, photoelectric conversion layer 44, and p-type layer 45 are sequentially formed to have thicknesses of 50 nm, 2 μm, and 15 nm, respectively. The n-type layer 43, photoelectric conversion layer 44, and p-type layer 45 form a power generation unit.

According to the embodiment 2, the p-type layer 45 is a p-type amorphous SiC layer, the n-type layer 43 is an n-type microcrystal Si layer, and the photoelectric conversion layer 44 is a non-doped microcrystal Si layer. The n-type layer 43 has a preferred orientation plane of (111), and the photoelectric conversion layer 44 has a preferred orientation plane of (220). The surface of the n-type layer 43 has pyramid-like irregularities, and the surface of the photoelectric conversion layer 44 is substantially flat and has gentle irregularities. The n-type layer 43 is an example of the “first semiconductor layer,” “non-monocrystal semiconductor layer,” or “non-monocrystal silicon layer” of the present invention. The photoelectric conversion layer 44 is an example of the “second semiconductor layer,” “non-monocrystal semiconductor layer,” or “non-monocrystal silicon layer” of the present invention. The p-type layer 45 is an example of the “third semiconductor layer” or “amorphous semiconductor layer” of the present invention.

Formed on the p-type layer 45 is a surface transparent electrode 46 that has a thickness of 80 nm and is made of ITO. Formed in a predetermined region on the surface transparent electrode 46 is a collector electrode 47 that has a thickness of 2 μm and is made of Ag. According to the photovoltaic device of the embodiment 2, light is made incident to a side (p-side) where the collector electrodes 47 are formed.

Manufacturing of the photovoltaic device

Processes of manufacturing the photovoltaic device according to the embodiment 2 will be explained. In FIG. 9, a stainless plate 1a and a polyimide resin layer 1b are prepared to form a substrate 1. On the substrate 1, a rear electrode 2 is formed. A plasma CVD method is employed to sequentially form, on the rear electrode 2, semiconductor layers that form a power generation unit. According to the embodiment 2, the sequentially formed are an n-type microcrystal Si layer serving as the n-type layer 43, a non-doped microcrystal Si layer serving as the photoelectric conversion layer 44, and a p-type amorphous SiC layer serving as the p-type layer 45. At this time, the embodiment 2 forms the n-type layer 43 to have a preferred orientation plane of (111) and the photoelectric conversion layer 44 to have a preferred orientation plane of (220). The n-type layer 43, photoelectric conversion layer 44, and p-type layer 45 have thicknesses of 50 nm, 2 μm, and 15 nm, respectively. Conditions to form the n-type layer 43, photoelectric conversion layer 44, and p-type layer 45 are as mentioned in Table 6.

TABLE 6

| | Substrate | Reaction | | Gas flow |
|---|---|---|---|---|
| | temperature | pressure | Incident | rate |
| Embodiment 2 | (° C.) | (Pa) | power (W) | (sccm) |
| N-type layer | 160 | 133 | 100 | SiH₄: 2 |
| | | | | H₂: 200 |
| | | | | PH₃: 0.2 |
| Photoelectric | 200 | 133 | 30 | SiH₄: 20 |
| conversion layer | | | | H₂: 400 |
| P-type layer | 160 | 33 | 10 | SiH₄: 10 |
| | | | | H₂: 190 |
| | | | | CH₄: 10 |
| | | | | B₂H₆: 0.4 |

As shown in Table 6, the n-type layer 43, i.e., the n-type microcrystal Si layer having a preferred orientation plane of (111) is formed with a substrate temperature of 160° C., a reaction pressure of 133 Pa, and a high-frequency power of 100 W. When forming the n-type layer 43, gas flow rates are set as 2 sccm for SiH₄ gas, 200 sccm for H₂ gas, and 0.2 sccm for PH₃ gas. The photoelectric conversion layer 44, i.e., the non-doped microcrystal Si layer having a preferred orientation plane of (220) is formed with a substrate temperature of 200° C., a reaction pressure of 133 Pa, and a high-frequency power of 30 W. When forming the photoelectric conversion layer 44, gas flow rates are set as 20 sccm for SiH₄ gas and 400 sccm for H₂ gas. The p-type layer 45, i.e., the p-type amorphous SiC layer is formed with a substrate temperature of 160° C., a reaction pressure of 33 Pa, and a high-frequency power of 10 W. When forming the p-type layer 45, gas flow rates are set as 10 sccm for SiH₄ gas, 190 sccm for H₂ gas, 10 sccm for CH₄ gas, and 0.4 sccm for B₂H₆ gas.

FIG. 10 is a graph showing X-ray diffraction peak strengths measured on the n-type layer 43, photoelectric conversion layer 44, and p-type layer 45 of the photovoltaic device of the embodiment 2 shown in FIG. 9 formed under the conditions of Table 6.

It is understood from FIG. 10 that the (111) diffraction peak strength of the n-type layer 43 is higher than the (220) diffraction peak strength thereof. The (220) diffraction peak strength of the photoelectric conversion layer 44 is higher than the (111) diffraction peak strength thereof. The p-type layer 45 has no diffraction peak. Namely, the graph of FIG. 10 confirms that, according to the embodiment 2, the n-type layer 43 has a preferred orientation plane of (111), the photoelectric conversion layer 44 has a preferred orientation plane of (220), and the p-type layer 45 is amorphous. According to the embodiment 2 shown in FIG. 9, the surface of the n-type layer 43 has pyramid-like irregularities and the surface of the photoelectric conversion layer 44 is substantially flat. Thereafter, like the embodiment 1, an RF magnetron sputtering method is employed to form, on the p-type layer 45, a surface transparent electrode 46 of 80 nm thick from ITO. A vacuum vapor deposition method is employed to form, in a predetermined region on the surface transparent electrode 46, a collector electrode 47 of 2 μm thick from Ag. This completes the photovoltaic device of FIG. 9 according to the embodiment 2.

### COMPARATIVE EXAMPLE 4

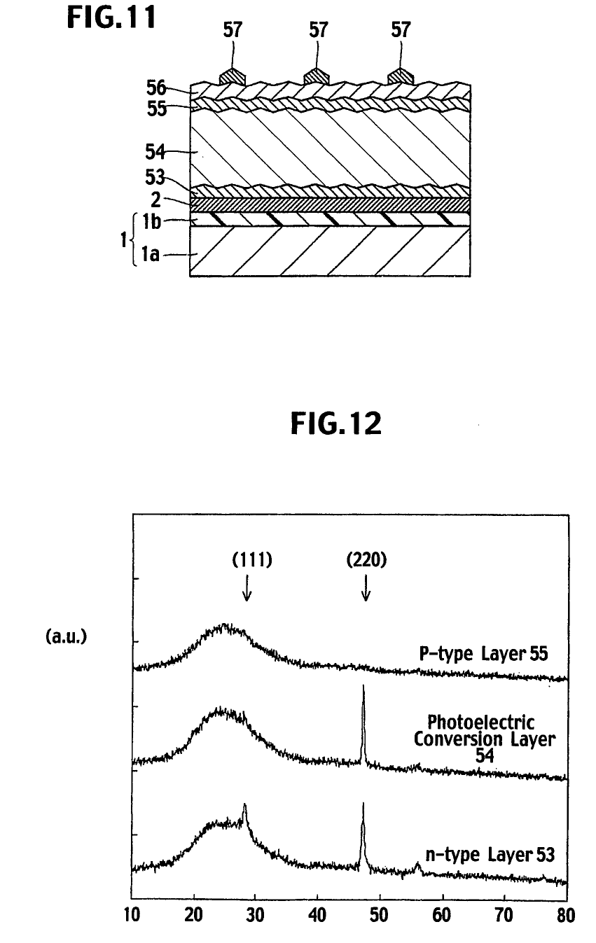

Photovoltaic devices according to comparative examples 4 and 5 will be explained in connection with the embodiment 2. FIG. 11 is a sectional view showing the structure of the photovoltaic device according to the comparative example 4. FIG. 12 is a graph showing the X-ray diffraction peak strengths of an n-type layer, a photoelectric conversion layer, and a p-type layer of the photovoltaic device of the comparative example 4 shown in FIG. 11. With reference to FIGS. 11 and 12, processes of manufacturing the photovoltaic device according to the comparative example 4 will be explained. Unlike the embodiment 2, the comparative example 4 employs a microcrystal Si layer having a preferred orientation plane of (220) for each of the n-type layer and photoelectric conversion layer, and an amorphous SiC layer for the p-type layer.

Manufacturing of the photovoltaic device

In FIG. 11, like the embodiment 1, a stainless plate 1a and a polyimide resin layer 1b are prepared to form a substrate 1. On the substrate 1, a rear electrode 2 is formed. A plasma CVD method is employed to sequentially form, on the rear electrode 2, semiconductor layers that form a powergeneration unit. According to the comparative example 4, the sequentially formed are an n-type microcrystal Si layer serving as the n-type layer 53, a non-doped microcrystal Si layer serving as the photoelectric conversion layer 54, and a p-type amorphous SiC layer serving as the p-type layer 55. At this time, the comparative example 4 forms each of the n-type layer 53 and photoelectric conversion layer 54 to have a preferred orientation plane of (220). The n-type layer 53, photoelectric conversion layer 54, and p-type layer 55 have thicknesses of 50 nm, 2 μm, and 15 nm, respectively. Conditions to form the n-type layer 53, photoelectric conversion layer 54, and p-type layer 55 are as mentioned in Table 7.

TABLE 7

| | Substrate | Reaction | | Gas flow |
|---|---|---|---|---|
| Comparative | temperature | pressure | Incident | rate |
| example 4 | (° C.) | (Pa) | power (W) | (sccm) |
| N-type layer | 160 | 133 | 100 | SiH₄: 3 |
| | | | | H₂: 200 |
| | | | | PH₃: 0.6 |
| Photoelectric | 200 | 133 | 30 | SiH₄: 20 |
| conversion layer | | | | H₂: 400 |
| P-type layer | 160 | 33 | 10 | SiH₄: 10 |
| | | | | H₂: 190 |
| | | | | CH₄: 10 |
| | | | | B₂H₆: 0.4 |

As shown in Table 7, the n-type layer 53, i.e., the n-type microcrystal Si layer having a preferred orientation plane of (220) is formed with a substrate temperature of 160° C., a reaction pressure of 133 Pa, and a high-frequency power of 100 W. When forming the n-type layer 53, gas flow rates are set as 3 sccm for SiH₄ gas, 200 sccm for H₂ gas, and 0.6 scam for PH₃ gas.

The photoelectric conversion layer 54, i.e., the non-doped microcrystal Si layer having a preferred orientation plane of (220) is formed with a substrate temperature of 200° C., a reaction pressure of 133 Pa, and a high-frequency power of 30 W. When forming the photoelectric conversion layer 54, gas flow rates are set as 20 scam for SiH₄ gas and 400 scam for H₂ gas. The conditions to form the photoelectric conversion layer 54 are the same as those for the photoelectric conversion layer 44 of the embodiment 2.

The p-type layer 55, i.e., the p-type amorphous SiC layer is formed with a substrate temperature of 160° C., a reaction pressure of 33 Pa, and a high-frequency power of 10 W. When forming the p-type layer 45, gas flow rates are set as 10 scam for SiH₄ gas, 190 scam for H₂ gas, 10 scam for CH₄ gas, and 0.4 scam for B₂H₆ gas. The conditions to form the p-type layer 55 are the same as those for the p-type layer 45 of the embodiment 2.

FIG. 12 is a graph showing X-ray diffraction peak strengths measured on the n-type layer 53, photoelectric conversion layer 54, and p-type layer 55 of the photovoltaic device of the comparative example 4 shown in FIG. 11 formed under the conditions shown in Table 7. It is understood from FIG. 12 that the n-type layer 53 and photoelectric conversion layer 54 have substantially the same X-ray diffraction spectrum. The (220) diffraction peak strength of each of the n-type layer 53 and photoelectric conversion layer 54 is higher than the (111) diffraction peak strength thereof. The p-type layer 55 has no diffraction peak. Namely, the graph of FIG. 12 confirms that, according to the comparative example 4, the n-type layer 53 and photoelectric conversion layer 54 each have a preferred orientation plane of (220) and the p-type layer 55 is amorphous. According to the comparative example 4 shown in FIG. 11, the surfaces of the n-type layer 53 and photoelectric conversion layer 54 are substantially flat.

Thereafter, like the embodiment 1, an RF magnetron sputtering method is employed to form, on the p-type layer 55, a surface transparent electrode 56 of 80 nm thick from ITO. A vacuum vapor deposition method is employed to form, in a predetermined region on the surface transparent electrode 56, a collector electrode 57 of 2 μm thick from Ag. This completes the photovoltaic device of FIG. 11 according to the comparative example 4. According to the photovoltaic device of the comparative example 4, light is made incident to a side (p-side) where the collector electrodes 57 are formed.

### COMPARATIVE EXAMPLE 5

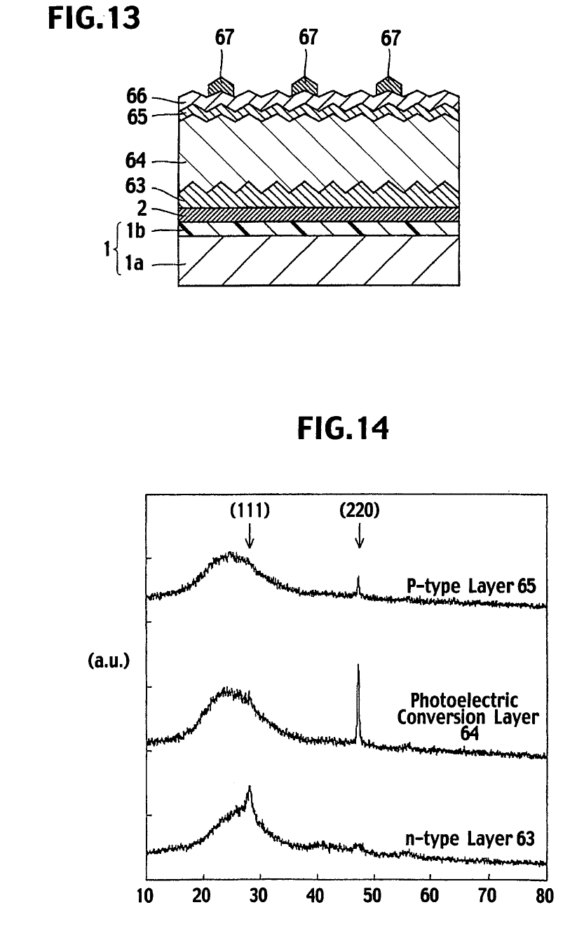

FIG. 13 is a sectional view showing the structure of a photovoltaic device according to the comparative example 5. FIG. 14 is a graph showing the X-ray diffraction peak strengths of an n-type layer, a photoelectric conversion layer, and a p-type layer of the photovoltaic device of the comparative example 5 shown in FIG. 13. With reference to FIGS. 13 and 14, processes of manufacturing the photovoltaic device according to the comparative example 5 will be explained. Unlike the embodiment 2, the comparative example 5 employs a microcrystal Si layer having a preferred orientation plane of (111) as the n-type layer and a microcrystal Si layer having a preferred orientation plane of (220) as each of the photoelectric conversion layer and p-type layer.

Manufacturing of the photovoltaic device

In FIG. 13, like the embodiment 1, a stainless plate 1a and a polyimide resin layer 1b are prepared to form a substrate 1. On the substrate 1, a rear electrode 2 is formed. A plasma CVD method is employed to sequentially form, on the rear electrode 2, semiconductor layers that form a power generation unit. According to the comparative example 5, the sequentially formed are an n-type microcrystal Si layer serving as the n-type layer 63, a non-doped microcrystal Si layer serving as the photoelectric conversion layer 64, and a p-type microcrystal Si layer serving as the p-type layer 65. At this time, the comparative example 5 forms the n-type layer 63 to have a preferred orientation plane of (111) and the photoelectric conversion layer 64 and p-type layer 65 to have a preferred orientation plane of (220). The n-type layer 63, photoelectric conversion layer 64, and p-type layer 65 have thicknesses of 50 nm, 2 μm, and 15 nm, respectively. Conditions to form the n-type layer 63, photoelectric conversion layer 64, and p-type layer 65 are as mentioned in Table 8.

TABLE 8

| | Substrate | Reaction | | Gas flow |
|---|---|---|---|---|
| Comparative | temperature | pressure | Incident | rate |
| example 5 | (° C.) | (Pa) | power (W) | (sccm) |
| N-type layer | 160 | 133 | 100 | SiH₄: 2 |
| | | | | H₂: 200 |
| | | | | PH₃: 0.2 |
| Photoelectric | 200 | 133 | 30 | SiH₄: 20 |
| conversion layer | | | | H₂: 400 |
| P-type layer | 160 | 133 | 60 | SiH₄: 2 |
| | | | | H₂: 150 |
| | | | | B₂H₆: 0.2 |

As shown in Table 8, the n-type layer 63, i.e., the n-type microcrystal Si layer having a preferred orientation plane of (111) is formed with a substrate temperature of 160° C., a reaction pressure of 133 Pa, and a high-frequency power of 100 W. When forming the n-type layer 63, gas flow rates are set as 2 sccm for SiH₄ gas, 200 sccm for H₂ gas, and 0.2 sccm for PH₃ gas. The conditions to form the n-type layer 63 are the same as those for the n-type layer 43 of the embodiment 2.

The photoelectric conversion layer 64, i.e., the non-doped microcrystal Si layer having a preferred orientation plane of (220) is formed with a substrate temperature of 200° C., a reaction pressure of 133 Pa, and a high-frequency power of 30 W. When forming the photoelectric conversion layer 64, gas flow rates are set as 20 sccm for SiH₄ gas and 400 sccm for H₂ gas. The conditions to form the photoelectric conversion layer 64 are the same as those for the photoelectric conversion layer 44 of the embodiment 2.

The p-type layer 65, i.e., the p-type microcrystal Si layer having a preferred orientation plane of (220) is formed with a substrate temperature of 160° C., a reaction pressure of 133 Pa, and a high-frequency power of 60 W. When forming the p-type layer 65, gas flow rates are set as 2 sccm for SiH₄ gas, 150 sccm for H₂ gas, and 0.2 sccm for B₂H₆ gas.

FIG. 14 is a graph showing X-ray diffraction peak strengths measured on the n-type layer 63, photoelectric conversion layer 64, and p-type layer 65 of the photovoltaic device of the comparative example 5 shown in FIG. 13 formed under the conditions shown in Table 8. It is understood from FIG. 14 that the (111) diffraction peak strength of the n-type layer 63 is higher than the (220) diffraction peak strength thereof. The photoelectric conversion layer 64 and p-type layer 65 have substantially the same X-ray diffraction spectrum. The (220) diffraction peak strength of each of the photoelectric conversion layer 64 and p-type layer 65 is higher than the (111) diffraction peak strength thereof. Namely, the graph of FIG. 14 confirms that, according to the comparative example 5, the n-type layer 63 has a preferred orientation plane of (111) and the photoelectric conversion layer 64 and p-type layer 65 each have a preferred orientation plane of (220). According to the comparative example 5 shown in FIG. 13, the surface of the n-type layer 63 has pyramid-like irregularities and the surfaces of the photoelectric conversion layer 64 and p-type layer 65 are substantially flat.

Thereafter, like the embodiment 1, an RF magnetron sputtering method is employed to form, on the p-type layer 65, a surface transparent electrode 66 of 80 nm thick from ITO. A vacuum vapor deposition method is employed to form, in a predetermined region on the surface transparent electrode 66, a collector electrode 67 of 2 μm thick from Ag. This completes the photovoltaic device of FIG. 13 according to the comparative example 5. According to the photovoltaic device of the comparative example 5, light is made incident to a side (p-side) where the collector electrodes 67 are formed.

Output performance test on embodiment 2 and comparative examples 4 and 5 To measure the output performance of the photovoltaic devices according to the embodiment 2 and comparative examples 4 and 5, the same output performance test as that for the embodiment 1 and comparative examples 1 to 3 is carried out. Namely, the test is carried out with the use of a solar simulator at a light spectrum of AM 1.5, a light intensity of 100 mW/cm², and a measuring temperature of 25° C. Results of measurement obtained from the test are shown in Table 9. The normalized conversion efficiency, normalized open-circuit voltage, and normalized short-circuit current shown in Table 9 are values normalized with the conversion efficiency, open-circuit voltage, and short-circuit current of the comparative example 2 serving as a reference value “1.”

TABLE 9

| | Normalized | Normalized | Normalized |
|---|---|---|---|
| | conversion | open-circuit | short-circuit |
| | efficiency | voltage | current |
| Embodiment 2 | 1.05 | 1.05 | 1.02 |
| Comparative example 4 | 1.02 | 1.04 | 1.01 |
| Comparative example 5 | 1.00 | 0.99 | 1.01 |
| Comparative example 2 | 1.00 | 1.00 | 1.00 |

Table 9 shows that, with the p-type layer being a p-type amorphous SiC layer, the embodiment 2 with the n-type layer 43 having a preferred orientation plane of (111) has a higher short-circuit current than the comparative example 4 with the n-type layer 53 having a preferred orientation plane of (220). More precisely, the embodiment 2 and comparative example 4 demonstrate normalized short-circuit current values of 1.02 and 1.01, respectively. This is because the embodiment 2 arranges, on the rear side, the n-type layer 43 whose surface has pyramid-like irregularities to scatter incident light and realize a good light trapping effect. As a result, the photoelectric conversion layer 44 of the embodiment 2 can efficiently absorb the incident light. On the other hand, the comparative example 4 arranges, on the rear side, the n-type layer 53 whose surface is nearly flat, to hardly realize a good light trapping effect on the rear side. The embodiment 2 and comparative example 4 realize normalized open-circuit voltage values of 1.05 and 1.04, respectively.

Comparison between the embodiment 2 and the comparative example 4 tells that the conversion efficiency (1.05) of the embodiment 2 is higher than the conversion efficiency (1.02) of the comparative example 4. This indicates that arranging, on the rear side, the n-type layer 43 whose surface has pyramid-like irregularities increases the conversion efficiency.

Table 9 also proves that the embodiment 2 employing an amorphous SiC layer as the p-type layer 45 among the semiconductor layers that form a power generation unit has a higher open-circuit voltage than any one of the comparative examples 2 and 5 each employing microcrystal Si layers for all of the semiconductor layers that form a power generation unit. More precisely, the normalized open-circuit voltage of the embodiment 2 is 1.05, that of the comparative example 2 is 1.00, and that of the comparative example 5 is 0.99. The reason of this may be that the embodiment 2 forms the p-type layer 45 with an amorphous SiC layer having a large band gap, thereby increasing a built-in electric field at a pin junction of the n-type layer 43, photoelectric conversion layer 44, and p-type layer 45. On the other hand, each of the comparative examples 2 and 5 forms each of the semiconductor layers of a power generation unit from a microcrystal Si layer having a small band gap, to reduce a built-in electric field at a pin junction of the n-type layer 23 (63), photoelectric conversion layer 24 (64), and p-type layer 25 (65) smaller than that of the embodiment 2.

Table 9 also clarifies that the embodiment 2 employing an amorphous SiC layer as the p-type layer 45 among the semiconductor layers of a power generation unit has a larger short-circuit current than any one of the comparative examples 2 and 5 each employing a microcrystal Si layer for every semiconductor layer of a power generation unit. More precisely, the normalized short-circuit current of the embodiment 2 is 1.02, that of the comparative example 2 is 1.00, and that of the comparative example 5 is 1.01. By forming the p-type layer 45 with an amorphous SiC layer having a large band gap, the embodiment 2 can reduce the light absorption loss of the p-type layer 45, thereby efficiently absorbing incident light by the photoelectric conversion layer 44. On the other hand, by forming the n-type layer 23 (63) with a microcrystal Si layer of small band gap, the comparative examples 2 and 5 each cause a larger light absorption loss in the n-type layer 23 (63) than the embodiment 2, thereby reducing incident light absorption by the photoelectric conversion layer 24 (64) smaller than that of the embodiment 2.

Comparison between the embodiment 2 and the comparative examples 2 and 5 tells that the conversion efficiency (1.05) of the embodiment 2 is higher than the conversion efficiency (1.00) of the comparative example 2 or 5. This indicates that forming the p-type layer 45 with an amorphous SiC layer increases the conversion efficiency.

As mentioned above, the embodiment 2 employs an amorphous SiC layer as the p-type layer 45 among the semiconductor layers that form a power generation unit. The amorphous SiC layer has a larger band gap than a microcrystal Si layer, and therefore, can increase a built-in electric field that is a potential difference between the Fermi level of the n-type layer 43 and the Fermi level of the p-type layer 45. This results in increasing the open-circuit voltage of the photovoltaic device. The amorphous Si layer that forms the n-type layer 43 does not absorb long-wavelength light that has lower energy than the bandgap of the amorphous Si layer. Namely, the amorphous SiC layer having a large band gap hardly absorbs light, thereby reducing the light absorption loss of the p-type layer 45. This makes the photoelectric conversion layer 44 efficiently absorb incident light, to increase the short-circuit current of the photovoltaic device.

The embodiment 2 employs a microcrystal Si layer having a preferred orientation plane of (111) to form the n-type layer 43 among the semiconductor layers that form a power generation unit. Even if the surfaces of the semiconductor layers except the n-type layer 43 are ubstantially flat, the n-type layer 43 will have an irregular surface to scatter incident light. Consequently, the power generation unit including the n-type layer 43, photoelectric conversion layer 44, and p-type layer 45 can realize a good light trapping effect, the photoelectric conversion layer 44 can efficiently absorb incident light, and the photovoltaic device can provide a large short-circuit current. In this way, the photovoltaic device according to the embodiment 2 can realize a large open-circuit voltage and a large short-circuit current to improve output performance. The embodiment 2 arranges an amorphous SiC layer serving as the p-type layer 45 on the light incident side, to reduce a light absorption loss by the p-type layer 45 arranged on the light incident side. As a result, the photoelectric conversion layer 44 can efficiently absorb incident light. According to the embodiment 2, the photoelectric conversion layer 44 has a preferred orientation plane of (220) to provide the photoelectric conversion layer 44 with proper characteristics and improve the output performance of the photovoltaic device.

### Embodiment 3

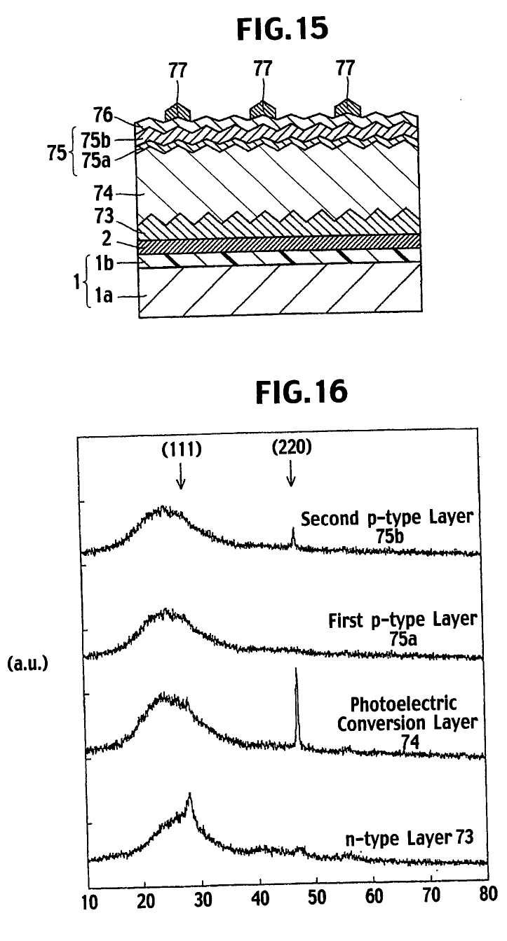

FIG. 15 is a sectional view showing the structure of a photovoltaic device according to an embodiment 3 of the present invention. Unlike the embodiments 1 and 2, the embodiment 3 employs a p-type layer having a two-layer structure. The structure of the photovoltaic device according to the embodiment 3 will be explained.

Like the embodiment 1, the photovoltaic device of the embodiment 3 shown in FIG. 15 employs a stainless plate 1a and a polyimide resin layer 1b to form a substrate 1. On the substrate 1, a rear electrode 2 is formed. On the rear electrode 2, an n-type layer 73, a photoelectric conversion layer 74, and the p-type layer 75 are sequentially formed to have thicknesses of 50 nm, 2 μm, and 20 nm, respectively. The p-type layer 75 includes a first p-type layer 75a formed on the photoelectric conversion layer 74 to a thickness of 15 nm and a second p-type layer 75b formed on the first p-type layer 75a to a thickness of 5 nm. The n-type layer 73, photoelectric conversion layer 74, and p-type layer 75 form a power generation unit. According to the embodiment 3, the first p-type layer 75a is a p-type amorphous SiC layer, the n-type layer 73 is an n-type microcrystal Si layer, the photoelectric conversion layer 74 is a non-doped microcrystal Si layer, and the second p-type layer 75b is a p-type microcrystal Si layer. The n-type layer 73 has a preferred orientation plane of (111), and each of the photoelectric conversion layer 74 and second p-type layer 75b has a preferred orientation plane of (220). The surface of the n-type layer 73 has pyramid-like irregularities, and the surfaces of the photoelectric conversion layer 74 and second p-type layer 75b are substantially flat and have gentle irregularities. The n-type layer 73 is an example of the “first semiconductor layer,” “non-monocrystal semiconductor layer,” or “non-monocrystal silicon layer” of the present invention.

The photoelectric conversion layer 74 is an example of the “second semiconductor layer,” “non-monocrystal semiconductor layer,” or “non-monocrystal silicon layer” of the present invention. The p-type layer 75 is an example of the “third semiconductor layer” of the present invention. The first p-type layer 75a is an example of the “amorphous semiconductor layer” of the present invention. The second p-type layer 75b is an example of the “non-monocrystal semiconductor layer” or “non-monocrystal silicon layer” of the present invention.

Formed on the p-type layer 75 (second p-type layer 75b) is a surface transparent electrode 76 that has a thickness of 80 nm and is made of ITO. The surface transparent electrode 76 is an example of the “electrode layer” of the present invention. Formed in a predetermined region on the surface transparent electrode 76 is a collector electrode 77 that has a thickness of 2 μm and is made of Ag. According to the photovoltaic device of the embodiment 3, light is made incident to a side (p-side) where the collector electrodes 77 are formed.

Manufacturing of the photovoltaic device

Processes of manufacturing the photovoltaic device according to the embodiment 3 will be explained. In FIG. 15, like the embodiment 1, a stainless plate 1a and a polyimide resin layer 1b are prepared to form a substrate 1. On the substrate 1, a rear electrode 2 is formed. A plasma CVD method is employed to sequentially form, on the rear electrode 2, semiconductor layers that form a power generation unit.

According to the embodiment 3, the sequentially formed are an n-type microcrystal Si layer serving as the n-type layer 73, a non-doped microcrystal Si layer serving as the photoelectric conversion layer 74, and the p-type layer 75. The p-type layer 75 is formed by successively forming a p-type amorphous SiC layer serving as the first p-type layer 75a and a p-type microcrystal Si layer serving as the second p-type layer 75b. The embodiment 3 forms the n-type layer 73 to have a preferred orientation plane of (111) and each of the photoelectric conversion layer 74 and second p-type layer 75b to have a preferred orientation plane of (220). The n-type layer 73, photoelectric conversion layer 74, first p-type layer 75a, and second p-type layer 75b have thicknesses of 50 nm, 2 am, 15 nm, and 5 nm, respectively. Conditions to form the n-type layer 73, photoelectric conversion layer 74, first p-type layer 75a, and second p-type layer 75b are as mentioned in Table 10.

TABLE 10

| | Substrate | Reaction | | Gas flow |
|---|---|---|---|---|
| | temperature | pressure | Incident | rate |
| Embodiment 3 | (° C.) | (Pa) | power (W) | (sccm) |
| N-type layer | 160 | 133 | 100 | SiH₄: 2 |
| | | | | H₂: 200 |
| | | | | PH₃: 0.2 |
| Photoelectric | 200 | 133 | 30 | SiH₄: 20 |
| conversion layer | | | | H₂: 400 |
| First p-type | 160 | 33 | 10 | SiH₄: 10 |
| layer | | | | H₂: 190 |
| | | | | CH₄: 10 |
| | | | | B₂H₆: 0.4 |
| Second p-type | 160 | 133 | 60 | SiH₄: 2 |
| layer | | | | H₂: 150 |
| | | | | B₂H₆: 0.2 |

As shown in Table 10, the n-type layer 73, i.e., the n-type microcrystal Si layer having a preferred orientation plane of (111) is formed with a substrate temperature of 160° C., a reaction pressure of 133 Pa, and a high-frequency power of 100 W. When forming the n-type layer 73, gas flow rates are set as 2 sccm for SiH₄ gas, 200 sccm for H₂ gas, and 0.2 sccm for PH₃ gas.

The photoelectric conversion layer 74, i.e., the non-doped microcrystal Si layer having a preferred orientation plane of (220) is formed with a substrate temperature of 200° C., a reaction pressure of 133 Pa, and a high-frequency power of 30 W. When forming the photoelectric conversion layer 74, gas flow rates are set as 20 sccm for SiH₄ gas and 400 sccm for H₂ gas. The first p-type layer 75a, i.e., the p-type amorphous SiC layer is formed with a substrate temperature of 160° C., a reaction pressure of 33 Pa, and a high-frequency power of 10 W. When forming the first p-type layer 75a, gas flow rates are set as 10 sccm for SiH₄ gas, 190 sccm for H₂ gas, 10 sccm for CH₄ gas, and 0.4 sccm for B₂H₆ gas. The second p-type layer 75b, i.e., the p-type microcrystal Si layer is formed with a substrate temperature of 160° C., a reaction pressure of 133 Pa, and a high-frequency power of 60 W. When forming the second p-type layer 75b, gas flow rates are set as 2 sccm for SiH₄ gas, 150 sccm for H₂ gas, and 0.2 sccm for B₂H₆ gas.

FIG. 16 is a graph showing X-ray diffraction peak strengths measured on the n-type layer 73, photoelectric conversion layer 74, first p-type layer 75a, and second p-type layer 75b of the photovoltaic device of the embodiment 3 shown in FIG. 15 formed under the conditions shown in Table 10. It is understood from FIG. 16 that the (111) diffraction peak strength of the n-type layer 73 is higher than the (220) diffraction peak strength thereof. The photoelectric conversion layer 74 and second p-type layer 75b have substantially the same X-ray diffraction spectrum. The (220) diffraction peak strength of each of the photoelectric conversion layer 74 and second p-type layer 75b is higher than the (111) diffraction peak strength thereof. The first p-type layer 75a has no diffraction peak. Namely, the graph of FIG. 16 confirms that, according to the embodiment 3, the n-type layer 73 has a preferred orientation plane of (111), the photoelectric conversion layer 74 and second p-type layer 75b each have a preferred orientation plane of (220), and the first p-type layer 75a is amorphous. According to the embodiment 3 shown in FIG. 15, the surface of the n-type layer 73 has pyramid-like irregularities and the surfaces of the photoelectric conversion layer 74 and second p-type layer 75b are substantially flat.

Thereafter, like the embodiment 1, an RF magnetron sputtering method is employed to form, on the p-type layer 75 (second p-type layer 75b), a surface transparent electrode 76 of 80 nm thick from ITO. A vacuum vapor deposition method is employed to form, in a predetermined region on the surface transparent electrode 76, a collector electrode 77 of 2 μm thick from Ag. This completes the photovoltaic device of FIG. 15 according to the embodiment 3.

### COMPARATIVE EXAMPLE 6

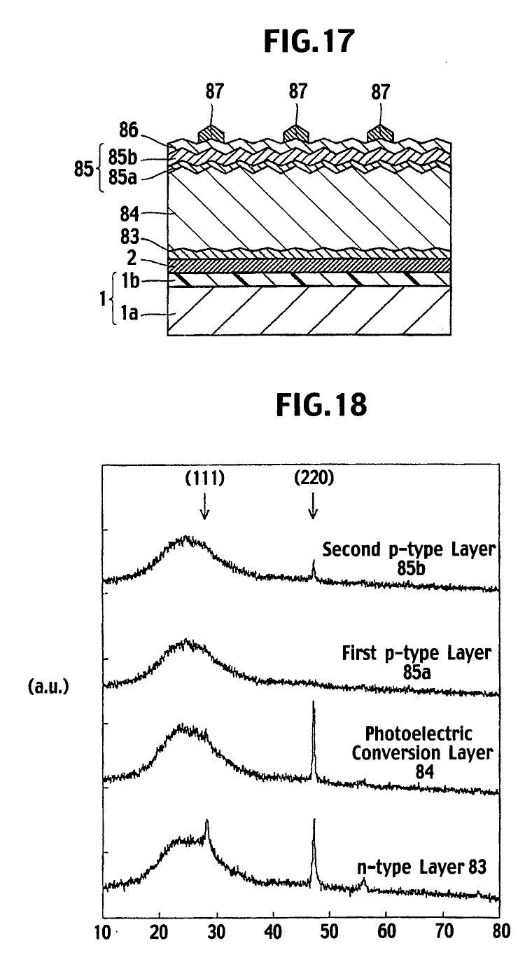

A photovoltaic device according to a comparative example 6 will be explained in connection with the embodiment 3. FIG. 17 is a sectional view showing the structure of the photovoltaic device according to the comparative example 6. FIG. 18 is a graph showing the X-ray diffraction peak strengths of an n-type layer, a photoelectric conversion layer, and a p-type layer of the photovoltaic device of the comparative example 6 shown in FIG. 17. With reference to FIGS. 17 and 18, processes of manufacturing the photovoltaic device according to the omparative example 6 will be explained. Unlike the embodiment 3, the omparative example 6 employs a microcrystal Si layer having a preferred rientation plane of (220) as each of the n-type layer, photoelectric conversion layer, and second p-type layer and an amorphous SiC layer as a first p-type layer.

Manufacturing of the photovoltaic device

In FIG. 17, like the embodiment 1, a stainless plate 1a and a polyimide resin layer 1b are prepared to form a substrate 1. On the substrate 1, a rear electrode 2 is formed. A plasma CVD method is employed to sequentially form, on the rear electrode 2, semiconductor layers that form a power generation unit. According to the comparative example 6, the sequentially formed are an n-type microcrystal Si layer serving as the n-type layer 83, a non-doped microcrystal Si layer serving as the photoelectric conversion layer 84, and a p-type layer 85. The p-type layer 85 is formed by successively forming a p-type amorphous SiC layer serving as the first p-type layer 85a and a p-type microcrystal Si layer serving as the second p-type layer 85b. The comparative example 6 forms each of the n-type layer 83, photoelectric conversion layer 84, and second p-type layer 85b to have a preferred orientation plane of (220). The n-type layer 83, photoelectric conversion layer 84, first p-type layer 85a, and second p-type layer 85b have thicknesses of 50 nm, 2 μm, 15 nm, and 5 nm, respectively. Conditions to form the n-type layer 83, photoelectric conversion layer 84, first p-type layer 85a, and second p-type layer 85b are as mentioned in Table 11.

TABLE 11

| | Substrate | Reaction | | Gas flow |
|---|---|---|---|---|
| Comparative | temperature | pressure | Incident | rate |
| example 6 | (° C.) | (Pa) | power (W) | (sccm) |
| N-type layer | 160 | 133 | 100 | SiH₄: 3 |
| | | | | H₂: 200 |
| | | | | PH₃: 0.6 |
| Photoelectric | 200 | 133 | 30 | SiH₄: 20 |
| conversion | | | | H₂: 400 |
| layer | | | | |
| First p-type | 160 | 33 | 10 | SiH₄: 10 |
| layer | | | | H₂: 190 |
| | | | | CH₄: 10 |
| | | | | B₂H₆: 0.4 |
| Second p-type | 160 | 133 | 60 | SiH₄: 2 |
| layer | | | | H₂: 150 |
| | | | | B₂H₆: 0.2 |

As shown in Table 11, the n-type layer 83, i.e., the n-type microcrystal Si layer having a preferred orientation plane of (220) is formed with a substrate temperature of 160° C., a reaction pressure of 133 Pa, and a high-frequency power of 100 W. When forming the n-type layer 83, gas flow rates are set as 3 sccm for SiH₄ gas, 200 sccm for H₂ gas, and 0.6 sccm for PH₃ gas. The photoelectric conversion layer 84, i.e., the non-doped microcrystal Si layer having a preferred orientation plane of (220) is formed with a substrate temperature of 200° C., a reaction pressure of 133 Pa, and a high-frequency power of 30 W. When forming the photoelectric conversion layer 84, gas flow rates are set as 20 sccm for SiH₄ gas and 400 sccm for H₂ gas. The conditions to form the photoelectric conversion layer 84 are the same as those for the photoelectric conversion layer 74 of the embodiment 3.

The first p-type layer 85a, i.e., the p-type amorphous SiC layer is formed with a substrate temperature of 160° C., a reaction pressure of 33 Pa, and a high-frequency power of 10 W. When forming the first p-type layer 85a, gas flow rates are set as 10 sccm for SiH₄ gas, 190 sccm for H₂ gas, 10 sccm for CH₄ gas, and 0.4 sccm for B₂H₆ gas. The conditions to form the first p-type layer 85a are the same as those for the first p-type layer 75a of the embodiment 3. The second p-type layer 85b, i.e., the p-type microcrystal Si layer is formed with a substrate temperatureof 1600C, areactionpressureof 133 Pa, andahigh-frequency power of 60 W. When forming the second p-type layer 85b, gas flow rates are set as 2 sccm for SiH₄ gas, 150 sccm for H₂ gas, and 0.2 sccm for B₂H₆ gas. The conditions to form the second p-type layer 85b are the same as those for the second p-type layer 75b of the embodiment 3.

FIG. 18 is a graph showing X-ray diffraction peak strengths measured on the n-type layer 83, photoelectric conversion layer 84, first p-type layer 85a, and second p-type layer 85b of the photovoltaic device of the comparative example 6 shown in FIG. 17 formed under the conditions shown in Table 11.

According to the comparative example 6, it is understood from FIG. 18 that the n-type layer 83, photoelectric conversion layer 84, and second p-type layer 85b have substantially the same X-ray diffraction spectrum. The (220) diffraction peak strength of each of the n-type layer 83, photoelectric conversion layer 84, and second p-type layer 85b is higher than the (111) diffraction peak strength thereof. The first p-type layer 85a has no diffraction peak. Namely, the graph of FIG. 18 confirms that, according to the comparative example 6, the n-type layer 83, photoelectric conversion layer 84, and second p-type layer 85b each have a preferred orientation plane of (220) and the first p-type layer 85a is amorphous. According to the comparative example 6 shown in FIG. 17, the surfaces of the n-type layer 83, photoelectric conversion layer 84 and second p-type layer 85b are substantially flat.

Thereafter, like the embodiment 1, an RF magnetron sputtering method is employed to form, on the p-type layer 85 (second p-type layer 85b), a surface transparent electrode 86 of 80 nm thick from ITO. A vacuum vapor deposition method is employed to form, in a predetermined region on the surface transparent electrode 86, a collector electrode 87 of 2 μm thick from Ag. This completes the photovoltaic device of FIG. 17 according to the comparative example 6. According to the photovoltaic device of the comparative example 6, light is made incident to a side (p-side) where the collector electrodes 87 are formed.

Output performance test on embodiment 3 and comparative example 6

To measure the output performance of the photovoltaic devices according to the embodiment 3 and comparative example 6, the same output performance test as that for the embodiment 1 and comparative examples 1 to 3 is carried out. Namely, the test is carried out with the use of a solar simulator at a light spectrum of AM 1.5, a light intensity of 100 mW/cm², and a measuring temperature of 25° C. Results of measurement obtained from the test are shown in Table 12. The normalized conversion efficiency, normalized open-circuit voltage, normalized short-circuit current, and normalized fill factor shown in Table 12 are values normalized with the conversion efficiency, open-circuit voltage, short-circuit current, and fill factor of the comparative example 2 serving as a reference value “1.”

TABLE 12

| | Normalized | Normalized | Normalized | Normalized |
|---|---|---|---|---|
| | conversion | open-circuit | short-circuit | fill |
| | efficiency | voltage | current | factor |
| Embodiment 3 | 1.07 | 1.05 | 1.02 | 1.00 |
| Embodiment 2 | 1.05 | 1.05 | 1.02 | 0.98 |
| Comparative | 1.02 | 1.04 | 0.99 | 0.99 |
| example 6 | | | | |
| Comparative | 1.00 | 1.00 | 1.00 | 1.00 |
| example 2 | | | | |

Table 12 shows that, with the p-type layer 75 having a two-layer structure including the first p-type layer 75a made of a p-type amorphous SiC layer and the second p-type layer 75b made of a p-type microcrystal Si layer on which the surface transparent electrode 76 is formed, the embodiment 3 can secure a fill factor better than the embodiment 2 that forms the surface transparent electrode 46 on the p-type layer 45 made of an amorphous SiC layer having a monolayer structure. More precisely, the normalized fill factor of the embodiment 3 is 1.00 and that of the embodiment 2 is 0.98. By forming the surface transparent electrode 76 on the second p-type layer (microcrystal Si layer) of the p-type layer 75, the embodiment 3 can prevent a contact resistance between the p-type layer 75 and the surface transparent electrode 76 from increasing. On the other hand, by forming the surface transparent electrode 46 on the p-type layer 45 made of an amorphous SiC layer having a monolayer structure, the embodiment 2 seems to increase a contact resistance between the p-type layer 45 and the surface transparent electrode 46. The embodiments 3 and 2 each demonstrate a normalized open-circuit voltage of 1.05 and a normalized short-circuit current of 1.02.

Comparison between the embodiments 3 and 2 tells that the conversion efficiency (1.07) of the embodiment 3 is higher than the conversion efficiency (1.05) of the embodiment 2. This indicates that providing the p-type layer 75 with a two-layer structure in which ap-type amorphous SiC layer serving as the first p-type layer 75a and a p-type microcrystal Si layer serving as the second p-type layer 75b are sequentially layered one on another can improve the conversion efficiency.

Table 12 shows that, with the p-type layer having a two-layer structure including a p-type amorphous SiC layer serving as the first p-type layer 75a, the embodiment 3 with the n-type layer 73 having a preferred orientation plane of (111) demonstrates a higher short-circuit current than the comparative example 6 with the n-type layer 83 having a preferred orientation plane of (220). More precisely, the embodiment 3 and comparative example 6 demonstrate normalized short-circuit current values of 1.02 and 0.99, respectively. This is because the embodiment 3 arranges, on the rear side, the n-type layer 73 whose surface has pyramid-like irregularities to scatter incident light and realize a good light trapping effect. As a result, the photoelectric conversion layer 74 of the embodiment 3 can efficiently absorb the incident light. On the other hand, the comparative example 6 arranges, on the rear side, the n-type layer 83 whose surface is nearly flat, to hardly realize a good light trapping effect on the rear side. The embodiment 3 and comparative example 6 show normalized open-circuit voltage values of 1.05 and 1.04, respectively, and normalized fill factor values of 1.00 and 0.99, respectively.

Comparison between the embodiment 3 and the comparative example 6 tells that the conversion efficiency (1.07) of the embodiment 3 is higher than the conversion efficiency (1.02) of the comparative example 6. This indicates that arranging, on the rear side, the n-type layer 73 whose surface has pyramid-like irregularities increases the conversion efficiency.

Table 12 also proves that the embodiment 3 employing an amorphous SiC layer as the first p-type layer 75a among the semiconductor layers that form a power generation unit has a higher open-circuit voltage than the comparative example 2 employing microcrystal Si layers for all of the semiconductor layers that form a power generation unit. More precisely, the normalized open-circuit voltage of the embodiment 3 is 1.05 and that of the comparative example 2 is 1.00. The reason of this may be that the embodiment 3 provides the p-type layer 75 with the two-layer structure including the first p-type layer 75a and second p-type layer 75b sequentially layered one on another and forms the first p-type layer 75a from a p-type amorphous SiC layer having a large band gap, thereby increasing a built-in electric field at a pin junction of the n-type layer 73, photoelectric conversion layer 74, and p-type layer 75. On the other hand, the comparative example 2 forms each of the semiconductor layers of a power generation unit from a microcrystal Si layer having a small band gap, to reduce a built-in electric field at a pin junction of the n-type layer 23, photoelectric conversion layer 24, and p-type layer 25 smaller than that of the embodiment 3.

Table 12 also clarifies that the embodiment 3 employing an amorphous SiC layer as the first p-type layer 75a among the semiconductor layers of a power generation unit has a larger short-circuit current than the comparative example 2 employing a microcrystal Si layer for every semiconductor layer of a power generation unit. More precisely, the normalized short-circuit current of the embodiment 3 is 1.02 and that of the comparative example 2 is 1.00. By providing the p-type layer 75 with the two-layer structure including the first p-type layer 75a and second p-type layer 75b sequentially layered one on another and by forming the first p-type layer 75a from an amorphous SiC layer having a large band gap, the embodiment 3 can reduce the light absorption loss of the p-type layer 75, thereby efficiently absorbing incident light in the photoelectric conversion layer 74. On the other hand, by providing the p-type layer 25 with a monolayer structure including a microcrystal Si layer having a small band gap, the comparative example 2 causes a larger light absorption loss in the p-type layer 25 than the embodiment 3, thereby reducing incident light absorption in the photoelectric conversion layer 24 smaller than that of the embodiment 3.

Comparison between the embodiment 3 and the comparative example 2 tells that the conversion efficiency (1.07) of the embodiment 3 is higher than the conversion efficiency (1.00) of the comparative example 2. This indicates that providing the p-type layer with the two-layer structure including the first p-type layer 75a and second p-type layer 75b sequentially layered one on another and forming the first p-type layer 75a with an amorphous SiC layer increase the conversion efficiency.

As mentioned above, the embodiment 3 provides the p-type layer 75 with a two-layer structure including a p-type amorphous SiC layer serving as the first p-type layer 75a and a p-type monocrystal Si layer serving as the second p-type layer 75b that are sequentially layered one on another. On the second p-type layer 75b, the embodiment 3 forms the surface transparent electrode 76. A microcrystal Si layer has a larger conductivity than an amorphous SiC layer, and therefore, a contact resistance between the p-type layer 75 (second p-type layer 75b) and the surface transparent electrode 76 is suppressed even if the p-type layer 75 includes the p-type amorphous SiC layer serving as the first p-type layer 75a. This results in securing the fill factor of the photovoltaic device according to the embodiment 3. The other effects of the embodiment 3 are the same as those of the embodiment 2.

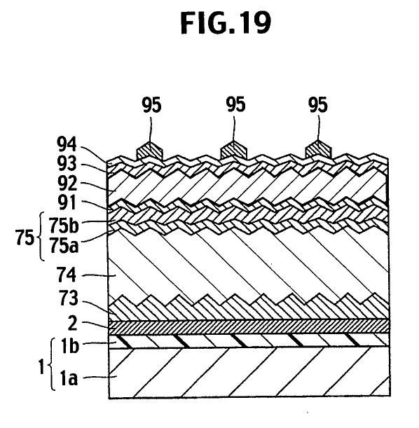

The embodiments disclosed herein are illustrative in all senses and are not intended to restrict the present invention. The scope of the present invention is presented not in the above-mentioned embodiments but in the appended claims. The scope of the present invention covers every amendment that is equivalent to or falls within the scope of the appended claims. For example, each photovoltaic device explained in connection with the embodiments 1 to 3 involves one power generation unit. This configuration is not intended to limit the present invention. The present invention is also applicable to a layered photovoltaic device involving a plurality of power generation units layered one on another. In such a structure, at least one of the plurality of power generation units may be the power generation unit of any one of the above-mentioned embodiments. FIG. 19 shows an example of the layered photovoltaic device. In FIG. 19, a second p-type layer 75b corresponds to the second p-type layer 75b of the embodiment 3 shown in FIG. 15. On the second p-type layer 75b of FIG. 19, an n-type microcrystal Si layer 91, a non-doped amorphous Si photoelectric conversion layer 92, and a p-type microcrystal Si layer 93 are successively formed to formapowergenerationunit. This configuration can provide the same effects as those provided by the above-mentioned embodiments. On the p-type layer 93, a surface transparent electrode 94 and collector electrodes 95 are formed like the above-mentioned embodiments.

On the other hand, the present invention is also applicable to a layered photovoltaic device involving a plurality of power generation units layered one on another. In such a structure, more than two of the plurality of power generation units may be the power generation unit of any one of the above-mentioned embodiments. FIG. 19 shows an example of the layered photovoltaic device. In FIG. 19, a second p-type layer 75b corresponds to the second p-type layer 75b of the embodiment 3 shown in FIG. 15. On the second p-type layer 75b of FIG. 19, an n-type microcrystal Si layer 91, a non-doped microcrystal Si photoelectric conversion layer 92, and a p-type amorphous Si layer 93 are successively formed to form a power generation unit. This configuration can provide the same effects as those provided by the above-mentioned embodiments. On the p-type layer 93, a surface transparent electrode 94 and collector electrodes 95 are formed like the above-mentioned embodiments.

Although the embodiments 1 to 3 each form a polyimide resin layer on a stainless plate, to prepare a substrate, the present invention is not limited to this. Instead of the stainless plate, a plate made of metal such as iron, molybdenum, and aluminum, or an alloy may be employed. Instead of the polyimide resin, other insulating material such as polyethersulfone (PES) and SiO₂ may be employed. Any combination of these metal and insulating materials is employable for the present invention.

According to the embodiments 1 to 3, the substrate includes a flat stainless plate on which a polyimide resin layer is formed to provide the substrate with a flat surface. The present invention is not limited to this. For example, the polyimide resin applied to the stainless plate may contain SiO₂ or TiO₂ grains having diameters of several hundreds of micrometers to provide the substrate with an irregular surface. In this case, the surface of a rear electrode formed on the substrate has irregularities due to the irregular surface of the substrate, to scatter incident light and improve a light trapping effect.

The present invention may be embodied in other specific forms without departing from the spirit or essential characteristics thereof.

The embodiments are therefore to be considered in all respects as illustrative and not restrictive, the scope of the present invention being indicated by the appended claims rather than by the foregoing description, and all changes which come within the meaning and range of equivalency of the claims are therefore intended to be embraced therein.

What is claimed is:

1. A photovoltaic device comprising:
at least one power generation unit including:
a first semiconductor layer of a first conductivity type, including at least one amorphous semiconductor layer;
a second semiconductor layer formed on the first semiconductor layer, the second semiconductor layer including at least one non-monocrystal semiconductor layer having crystallinity, being substantially intrinsic, the second semiconductor layer arranged and configured to carry out photoelectric conversion; and
a third semiconductor layer of a second conductivity type formed on the second semiconductor layer and including at least one non-monocrystal semiconductor layer whose preferred orientation plane is different from that of the non-monocrystal semiconductor layer of the second semiconductor layer.

2. The photovoltaic device as claimed in claim 1, wherein:
the first semiconductor layer is arranged on a substrate side relative to the third semiconductor layer, said substrate side is opposite to a light incident side.

3. The photovoltaic device as claimed in claim 2, wherein:
the first semiconductor layer includes a plurality of layers among which the amorphous semiconductor layer is arranged on the substrate side.

4. The photovoltaic device as claimed in claim 1, wherein:
the third semiconductor layer further comprises an amorphous emiconductor layer.

5. The photovoltaic device as claimed in claim 4, wherein:
the third semiconductor layer is arranged on a light incident side relative to the first semiconductor layer.

6. The photovoltaic device as claimed in claim 4, wherein:
in the third semiconductor layer, the non-monocrystal semiconductor layer having crystallinity is formed on the amorphous semiconductor layer.

7. The photovoltaic device as claimed in claim 6, further comprising:
an electrode layer formed on the non-monocrystal semiconductor layer having crystallinity of the third semiconductor layer.

8. The photovoltaic device as claimed in claim 1, wherein:
the non-monocrystal semiconductor layer having crystallinity and contained in the second and third semiconductor layers is a non-monocrystal silicon layer having crystallinity.

9. The photovoltaic device as claimed in claim 8, wherein:
at least one of the non-monocrystal silicon layers having rystallinity of the third semiconductor layers has a preferred rientation plane of (111).

10. The photovoltaic device as claimed in claim 9, wherein:
at least the non-monocrystal silicon layer having crystallinity of the second semiconductor layer has a preferred orientation plane of (220).

11. The photovoltaic device as claimed in claim 1, the power generation unit further comprising:
a fourth semiconductor layer of a first conductivity type formed on the third semiconductor layer, including at least one amorphous semiconductor layer;
a fifth semiconductor layer formed on the fourth semiconductor layer, the fifth semiconductor layer including at least one non-monocrystal semiconductor layer having crystallinity, being substantially intrinsic, the fifth semiconductor layer arranged and configured to carry out photoelectric conversion; and
a sixth semiconductor layer of a second conductivity type formed on the fifth semiconductor layer and including at least one non-monocrystal semiconductor layer whose preferred orientation plane is different from that of the non-monocrystal semiconductor layer of the fifth semiconductor layer.

12. A photovoltaic device comprising:
at least one power generation unit including:
a first semiconductor layer of a first conductivity type, including at least one non-monocrystal semiconductor layer;
a second semiconductor layer formed on the first semiconductor layer, the second semiconductor layer including at least one non-monocrystal semiconductor layer being substantially intrinsic and whose preferred orientation plane is different from that of the non-monocrystal semiconductor layer of the first semiconductor layer, the second semiconductor layer arranged and configured to carry out photoelectric conversion; and
a third semiconductor layer of a second conductivity type formed on the second semiconductor layer and including at least one amorphous semiconductor layer.

13. The photovoltaic device as claimed in claim 12, wherein:
the first semiconductor layer is arranged on a substrate side relative to the third semiconductor layer, said substrate side is opposite to a light incident side.

14. The photovoltaic device as claimed in claim 13, wherein:
the first semiconductor layer includes a plurality of layers among which the non-monocrystal semiconductor layer is arranged on the substrate side.

15. The photovoltaic device as claimed in claim 12, wherein:
the third semiconductor layer further comprises a non-monocrystal semiconductor layer.

16. The photovoltaic device as claimed in claim 15, wherein:
the third semiconductor layer is arranged on a light incident side relative to the first semiconductor layer.

17. The photovoltaic device as claimed in claim 15, wherein:
in the third semiconductor layer, the non-monocrystal semiconductor layer having crystallinity is formed on the amorphous semiconductor layer.

18. The photovoltaic device as claimed in claim 17, further comprising:
an electrode layer formed on the non-monocrystal semiconductor layer having crystallinity of the third semiconductor layer.

19. The photovoltaic device as claimed in claim 12, wherein:
the non-monocrystal semiconductor layer having crystallinity and contained in the first and the second semiconductor layers is a non-monocrystal silicon layer having crystallinity.

20. The photovoltaic device as claimed in claim 19, wherein:
at least one of the non-monocrystal silicon layers having crystallinity of the first semiconductor layers has a preferred orientation plane of (111).

21. The photovoltaic device as claimed in claim 20, wherein:
at least the non-monocrystal silicon layer having crystallinity of the second semiconductor layer has a preferred orientation plane of (220).

22. The photovoltaic device as claimed in claim 12, the power generation unit further comprising:
a fourth semiconductor layer of a first conductivity type formed on the third semiconductor layer, including at least one amorphous semiconductor layer;
a fifth semiconductor layer formed on the fourth semiconductor layer, the fifth semiconductor layer including at least one non-monocrystal semiconductor layer having crystallinity, being substantially intrinsic, the fifth semiconductor layer arranged and configured to carry out photoelectric conversion; and
a sixth semiconductor layer of a second conductivity type formed on the fifth semiconductor layer and including at least one non-monocrystal semiconductor layer whose preferred orientation plane is different from that of the non-monocrystal semiconductor layer of the fifth semiconductor layer.
